(19) United States
(12) Patent Application Publication
(10) Pub. No.: US 2025/0131929 A1
(43) Pub. Date: Apr. 24, 2025

(54) APPARATUS AND METHOD FOR ENCODING OR DECODING AR/VR METADATA WITH GENERIC CODEBOOKS

(71) Applicant: Fraunhofer-Gesellschaft zur Förderung der angewandten Forschung e.V., München (DE)

(72) Inventor: Christian BORß, Erlangen (DE)

(73) Assignee: Fraunhofer-Gesellschaft zur Förderung der angewandten Forschung e.V., München (DE)

(21) Appl. No.: 19/007,434

(22) Filed: Dec. 31, 2024

Related U.S. Application Data
(63) Continuation of application No. PCT/EP2023/069392, filed on Jul. 12, 2023.

(30) Foreign Application Priority Data
Jul. 12, 2022 (WO) PCT/EP2022/069523

(51) Int. Cl. G10L 19/018; G10L 19/00

(52) U.S. Cl. CPC G10L 19/018; G10L 2019/0006

(57) ABSTRACT

An apparatus for generating one or more audio output signals from one or more encoded audio signals according to an embodiment is provided. The apparatus comprises at least one entropy decoding module for decoding encoded additional audio information, when the encoded additional audio information is entropy-encoded, to obtain decoded additional audio information. Moreover, the apparatus comprises a signal processor for generating the one or more audio output signals depending on the one or more encoded audio signals and depending on the decoded additional audio information.

### CROSS-REFERENCES TO RELATED APPLICATIONS

This application is a continuation of copending International Application No. PCT/EP2023/069392, filed Jul. 12, 2023, which is incorporated herein by reference in its entirety, and additionally claims priority from International Application No. PCT/EP2022/069523, filed Jul. 12, 2022, which is incorporated herein by reference in its entirety.

The present invention relates to an apparatus and a method for encoding or decoding, and, in particular, to an apparatus and a method for encoding or decoding augmented reality (AR) or virtual reality (VR) metadata with generic codebooks.

### BACKGROUND OF THE INVENTION

Further improving and developing audio coding technologies is a continuous task of audio coding research, wherein, it is intended to create a realistic audio experience for a listener, for example in augmented reality or virtual reality scenarios that takes audio effects such as reverberation, e.g., caused by reflections at objects, walls, etc. into account, while, at the same time, it is intended to encode and decode audio information with high efficiency.

One of these new audio technologies that aim to create an improved listening experience for augmented or virtual reality is, for example, MPEG-I. MPEG-I is the new under-development standard for virtual and augmented reality applications. It aims at creating AR or VR experiences that are natural, realistic and deliver an overall convincing experience, not only for the eyes, but also for the ears.

For example, using MPEG-I technologies, when hearing a concert in VR, a listener is not rooted to just one spot, but can move freely around the concert hall. Or, for example, MPEG-I technologies may be employed for the broadcast of e-sports or sporting events in which users can move around the stadium while they watch the game.

Previous solutions enable a visual or acoustic experience from one observation point in what are known as the three degrees of freedom (3DoF). By contrast, the upcoming MPEG-I standard supports a full six degrees of freedom (6DoF). With 3DoF, users can move their heads freely and receive input from multiple sides. But with 6DoF, the user is able to move within the virtual space. They can walk around, explore every viewing angle, and even interact with the virtual world. MPEG-I technologies are likewise applicable for augmented reality (AR), in which the user acts within the real world that has been extended by virtual elements. For example, you could arrange several virtual musicians within your living room and enjoy your own personal concert.

To achieve this goal, MPEG-I provides a sophisticated technology to produce a convincing and highly immersive audio experience, and involves taking into account many aspects of acoustics. One example is sound propagation in rooms and around obstacles. Another is sound sources, which can be either static or in motion, wherein the latter produces the Doppler effect. The sound propagation shall have realistic radiation patterns and size. For example, MPEG-I technologies aim to take diffraction of sound around obstacles or room corners into account and aim to provide an efficient rendering of these effects.

Overall, MPEG-I aims to provide a long-term stable format for rich VR and AR content. Reproduction using MPEG-I shall be possible both with dedicated receiver devices and on everyday smartphones. MPEG-I aims to distribute VR and AR content as a next-generation video service over existing distribution channels, such that providers can offer users truly exciting and immersive experiences with entertainment, documentary, educational or sports content.

It is desirable that additional audio information, such as information on a real or virtual acoustic environment and/or their effects, such as reverberation, is provided for a decoder, for example, as additional audio information. Providing such information in an efficient way would be highly appreciated.

Summarizing the above, it would be highly appreciated, if improved concepts for audio encoding and audio decoding would be provided.

The object of the present invention is to provide improved concepts for audio encoding and audio decoding.

### SUMMARY

An embodiment may have an apparatus for generating one or more audio output signals from one or more encoded audio signals, wherein the apparatus comprises: at least one entropy decoding module for decoding encoded additional audio information, when the encoded additional audio information is entropy-encoded, to acquire decoded additional audio information, and a signal processor for generating the one or more audio output signals depending on the one or more encoded audio signals and depending on the decoded additional audio information.

Another embodiment may have an apparatus for encoding one or more audio signals and additional audio information, wherein the apparatus comprises: an audio signal encoder for encoding the one or more audio signals to acquire one or more encoded audio signals, and at least one entropy encoding module for encoding the additional audio information using entropy encoding to acquire encoded additional audio information.

Another embodiment may have a system comprising: an apparatus according to the invention for encoding one or more audio signals and additional audio information to acquire one or more encoded audio signals and encoded additional audio information, and an apparatus according to the invention for generating one or more audio output signals from the one or more encoded audio signals and depending on the encoded additional audio information.

Another embodiment may have a method for generating one or more audio output signals from one or more encoded audio signals, wherein the method comprises: decoding encoded additional audio information, when the encoded additional audio information is entropy-encoded, to acquire decoded additional audio information, and generating the one or more audio output signals depending on the one or more encoded audio signals and depending on the decoded additional audio information.

Another embodiment may have a method for encoding one or more audio signals and additional audio information, wherein the method comprises: encoding the one or more audio signals to one or more encoded audio signals, and encoding the additional audio information using entropy encoding to acquire encoded additional audio information.

Another embodiment may have a non-transitory digital storage medium having a computer program stored thereon to perform the method for generating one or more audio output signals from one or more encoded audio signals, wherein the method comprises: decoding encoded additional audio information, when the encoded additional audio information is entropy-encoded, to acquire decoded additional audio information, and generating the one or more audio output signals depending on the one or more encoded audio signals and depending on the decoded additional audio information, when said computer program is run by a computer.

Another embodiment may have a non-transitory digital storage medium having a computer program stored thereon to perform the method for encoding one or more audio signals and additional audio information, wherein the method comprises: encoding the one or more audio signals to one or more encoded audio signals, and encoding the additional audio information using entropy encoding to acquire encoded additional audio information, when said computer program is run by a computer.

An apparatus for generating one or more audio output signals from one or more encoded audio signals according to an embodiment is provided. The apparatus comprises at least one entropy decoding module for decoding encoded additional audio information, when the encoded additional audio information is entropy-encoded, to obtain decoded additional audio information. Moreover, the apparatus comprises a signal processor for generating the one or more audio output signals depending on the one or more encoded audio signals and depending on the decoded additional audio information.

Moreover, an apparatus for encoding one or more audio signals and additional audio information according to an embodiment is provided. The apparatus comprises an audio signal encoder for encoding the one or more audio signals to obtain one or more encoded audio signals. Furthermore, the apparatus comprises at least one entropy encoding module for encoding the additional audio information using entropy encoding to obtain encoded additional audio information.

Furthermore, an apparatus for generating one or more audio output signals from one or more encoded audio signals according to an embodiment is provided. The apparatus comprises an input interface for receiving the one or more encoded audio signals and for receiving additional audio information data. Furthermore, the apparatus comprises a signal generator for generating the one or more audio output signals depending on the encoded audio signals and depending on second additional audio information. The signal generator is configured to obtain the second additional audio information using the additional audio information data and using first additional audio information, if the additional audio information data exhibits a redundancy state. Moreover, the signal generator is configured to obtain the second additional audio information using the additional audio information data without using the first additional audio information, if the additional audio information data exhibits a non-redundancy state.

Moreover, an apparatus for encoding one or more audio signals and for generating additional audio information data according to an embodiment is provided. The apparatus comprises an audio signal encoder for encoding the one or more audio signals to obtain one or more encoded audio signals. Furthermore, the apparatus comprises a additional audio information generator for generating the additional audio information data, wherein the additional audio information generator exhibits a non-redundancy operation mode and a redundancy operation mode. The additional audio information generator is configured to generate the additional audio information data, if the additional audio information generator exhibits the non-redundancy operation mode, such that the additional audio information data comprises the second additional audio information. Moreover, the additional audio information generator is configured to generate the additional audio information data, if the additional audio information generator exhibits the non-redundancy operation mode, such that the additional audio information data does not comprise the second additional audio information or does only comprise a portion of the second additional audio information, such that the second additional audio information is obtainable using the additional audio information data together with first additional audio information.

Furthermore, a method for generating one or more audio output signals from one or more encoded audio signals according to an embodiment is provided. The method comprises:
Decoding encoded additional audio information, when the encoded additional audio information is entropy-encoded, to obtain decoded additional audio information. And:
Generating the one or more audio output signals depending on the one or more encoded audio signals and depending on the decoded additional audio information.

Moreover, a method for encoding one or more audio signals and additional audio information according to an embodiment is provided. The method comprises:
Encoding the one or more audio signals to one or more encoded audio signals. And:
Encoding the additional audio information using entropy encoding to obtain encoded additional audio information.

Furthermore, a method for generating one or more audio output signals from one or more encoded audio signals according to another embodiment is provided. The method comprises:
Receiving the one or more encoded audio signals and for receiving additional audio information data. And:
Generating the one or more audio output signals depending on the encoded audio signals and depending on second additional audio information.

The method comprises obtaining the second additional audio information using the additional audio information data and using first additional audio information, if the additional audio information data exhibits a redundancy state. Moreover, the method comprises obtaining the second additional audio information using the additional audio information data without using the first additional audio information, if the additional audio information data exhibits a non-redundancy state.

Furthermore, a method for encoding one or more audio signals and for generating additional audio information data according to an embodiment is provided. The method comprises:
Encoding the one or more audio signals to obtain one or more encoded audio signals. And:
Generating the additional audio information data.

In a non-redundancy operation mode, generating the additional audio information data is conducted, such that the additional audio information data comprises the second additional audio information. In a redundancy operation mode, generating the additional audio information data is conducted, such that the additional audio information data does not comprise the second additional audio information or does only comprise a portion of the second additional audio information, such that the second additional audio information is obtainable using the additional audio information data together with first additional audio information.

Furthermore, computer programs are provided, wherein each of the computer programs is configured to implement one of the above-described methods when being executed on a computer or signal processor.

### BRIEF DESCRIPTION OF THE DRAWINGS

Embodiments of the present invention will be detailed subsequently referring to the appended drawings, in which:

FIG. 1 illustrates an apparatus for generating one or more audio output signals from one or more encoded audio signals according to an embodiment.

FIG. 2 illustrates an apparatus for generating one or more audio output signals according to another embodiment, which further comprises at least one non-entropy decoding module and a selector.

FIG. 3 illustrates an apparatus for generating one or more audio output signals according to a further embodiment, wherein the apparatus comprises a non-entropy decoding module, a Huffman decoding module and an arithmetic decoding module.

FIG. 4 illustrates an apparatus for encoding one or more audio signals and additional audio information according to an embodiment.

FIG. 5 illustrates an apparatus for encoding one or more audio signals and additional audio information according to another embodiment, which comprises at least one non-entropy encoding module and a selector.

FIG. 6 illustrates an apparatus for generating one or more audio output signals according to a further embodiment, wherein the apparatus comprises a non-entropy encoding module, a Huffman encoding module and an arithmetic encoding module.

FIG. 7 illustrates a system according to an embodiment.

FIG. 8 illustrates a particular embodiment which depicts encoding of the additional audio data and decoding of the encoded additional audio data.

FIG. 9 illustrates an apparatus for generating one or more audio output signals from one or more encoded audio signals according to another embodiment.

FIG. 10 illustrates an apparatus for encoding one or more audio signals and for generating additional audio information data according to an embodiment.

FIG. 11 illustrates a system according to another embodiment.

### DETAILED DESCRIPTION OF THE INVENTION

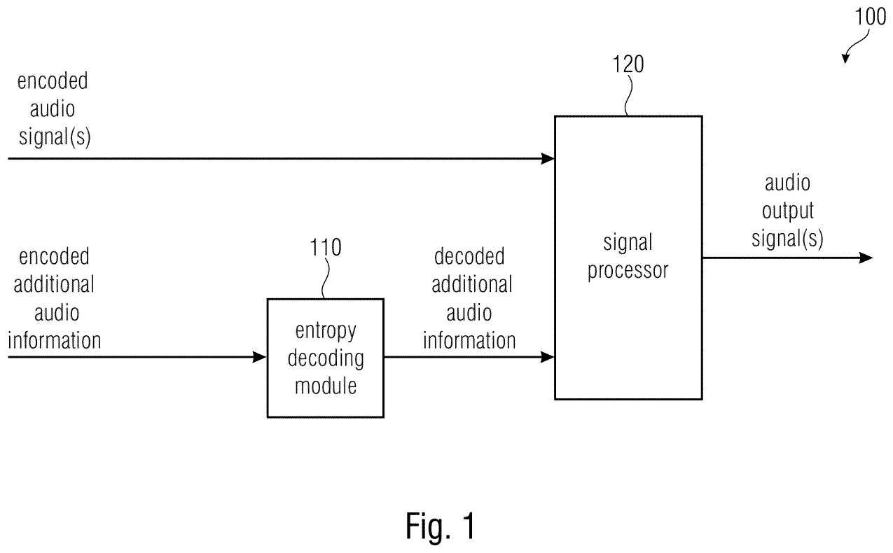

FIG. 1 illustrates an apparatus 100 for generating one or more audio output signals from one or more encoded audio signals according to an embodiment.

The apparatus 100 comprises at least one entropy decoding module 110 for decoding encoded additional audio information, when the encoded additional audio information is entropy-encoded, to obtain decoded additional audio information.

Moreover, the apparatus 100 comprises a signal processor 120 for generating the one or more audio output signals depending on the one or more encoded audio signals and depending on the decoded additional audio information.

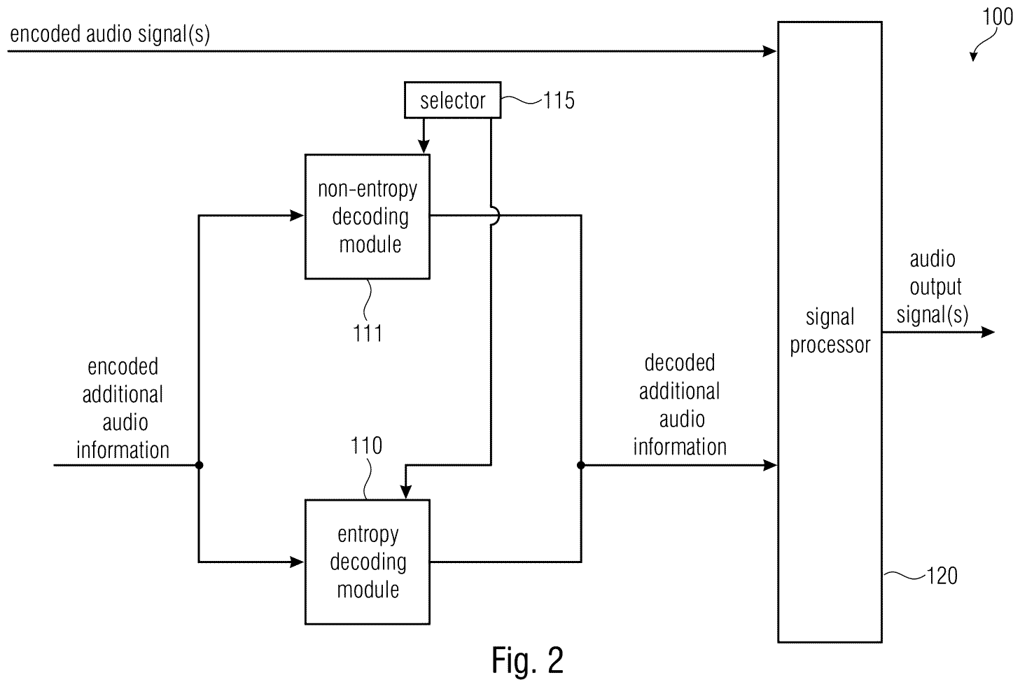

FIG. 2 illustrates an apparatus 100 for generating one or more audio output signals according to another embodiment, wherein, compared to the apparatus 100 of FIG. 1, the apparatus 100 of FIG. 2 further comprises at least one non-entropy decoding module 111 and a selector 115.

The at least one non-entropy decoding module 111 may, e.g., be configured to decode the encoded additional audio information, when the encoded additional audio information is not entropy-encoded, to obtain the decoded additional audio information.

The selector 115 may, e.g., be configured to select one of the at least one entropy decoding module 110 and of the at least one non-entropy decoding module 111 for decoding the encoded additional audio information depending on whether or not the encoded additional audio information is entropy-encoded.

According to an embodiment, the encoded additional audio information may, e.g., comprise augmented reality data or virtual reality data.

In an embodiment, the encoded additional audio information depends on a real listening environment or depends on a virtual listening environment or depends on an augmented listening environment.

In a typical application scenario, a listening environment shall be modelled and encoded on an encoder side and the modelling of the listening environment shall be received on a decoder side.

Typical additional audio information relating to a listening environment may, e.g., be information on a plurality of reflection objects, where sound waves may, e.g., be reflected. In general, reflection objects that are relevant for reflections are those that have an extension which is (significantly) greater than the wavelength of audible sound. Thus, when considering reflections, walls or other large reflection objects are of particular importance. Such reflection objects may, e.g., be suitably represented by surfaces, on which sounds are reflected.

In a three-dimensional environment, a surface may, for example, be characterized by three points in a three-dimensional coordinate system, where each of these three points may, e.g., be defined by its x-coordinate value, its y-coordinate value and its z-coordinate value. Thus, for each of the three points, three x-, y-, z-values would be needed, and thus, in total, nine coordinate values would be needed to define a surface.

A more efficient representation of a surface may, e.g., be achieved by defining the surface by using its normal vector no and by using a scalar distance value d which defines the distance from a defined origin to the surface. If the normal vector no of the surface is defined by an azimuth angle and an elevation angle (the length of the normal vector is 1 and thus does not have to be encoded), a surface can thus be defined by only three values, namely the scalar distance value d of the surface, and by the azimuth angle and elevation angle of the normal vector no of the surface.

Usually, for efficient encoding, the azimuth angle and the elevation angle may, e.g., be suitably quantized. For example, each azimuth angle may have one out of 2ⁿ different azimuth values and the elevation angles may, for example, be encoded such that each elevation angle may have one out of 2ⁿ⁻¹ different elevation values.

As outlined above, when defining a listening environment focusing on reflections, the representation of walls plays an important role. This is true for indoor scenarios where indoor walls play highly significant role for, e.g., early reflections. This is, however, also true for outdoor scenarios, where walls of buildings represent a major portion of relevant reflection objects.

It is observed that in usual environments, at lot of walls stand with an about 90° degree angle on each other. For example, in an indoor scenario, a lot of horizontal and vertical walls are present. While it has been found that due to construction deviations the relationship between the walls is not always exactly 90°, but, may, e.g., be 89.8°, 89.6°, 90.3° or similar, there is still a significant rate of walls that have a relationship with respect to each other around 90° and around 0°.

For example, an elevation angle of a wall may, e.g., be defined to be 0°, if the wall is a horizontal wall and may, e.g., be defined to be 90°, if the surface of the wall is a vertical wall. Then, in real-world examples there will be a significant rate of walls that have an elevation angle of about 90° (e.g., 89.8°, 89.7°, 90.2°) and a significant rate of walls that have an elevation angle of about 0° (e.g., 0.3°, −0.2°, 0.4°).

The same observation for elevation angles applies often for azimuth angles, as often, rooms have a rectangular shape.

Returning to the example of elevation angles, it should be noted that, however, if the 0° value of the elevation angle is defined differently than above, other values result that usual walls exhibit. For example, if a surface is defined to have a 0° elevation angle, if is inclined by 20° with respect to a horizontal plane, then a lot of real-world walls may, e.g., have an elevation angle of about −20° (e.g., −19.8°, −20.0°, −20.2°) and a lot of real-world walls may, e.g., have an elevation angle of about 70° (e.g., 69.8°, 70.0°, 70.2°). Still, a significant rate have walls will have same elevation angles at certain elevation angles (in this example at around −20° and at around) 70°. The same applies for azimuth angles.

Moreover, some other walls will have other certain typical elevation angles. For example, roofs are typically inclined by 45° or by 35° or by 30°. A certain frequentness of these values will also occur in real world-examples.

It is moreover noted that not all real-world rooms have a rectangular ground shape but may, for example, exhibit other regular shapes. For example, consider a room that has an octagonal ground shape. Although there, it may be assumed that some azimuth angles, for example, azimuth angles of about 0°, 45°, 90° and 135° occur more frequently than other azimuth angles.

Moreover, in outdoor examples, walls will often exhibit similar azimuth angles. For example, two parallel walls of one house will exhibit similar azimuth angles, but this may, e.g., also relate to walls of neighbouring houses that are often build in a row with a regular, similar ground shape with respect to each other. There also, walls of neighbouring houses will exhibit similar azimuth values, and thus have similarly oriented reflective walls/surfaces,

From the above-observation, it has been found that it is often particularly suitable to encode and decode additional audio information using entropy encoding. This applies particular for scenarios, where an occurrence of particular values out of all possible values occurs (significantly) more often than for other values.

In a particular embodiment, the values of elevation angles of surfaces (for example, representing reflection objects) may, e.g., be encoded and decoded using entropy coding, for example, using Huffman coding or using arithmetic coding.

Likewise, in a particular embodiment, the values of azimuth angles of surfaces (for example, representing reflection objects) may, e.g., be encoded and decoded using entropy coding, for example, using Huffman coding or using arithmetic coding.

The above considerations also apply for other application scenarios. For example, for a given audio source position s and, e.g., for a given listener position l, a reflection sequence may, e.g., define a number of one or more surfaces identified by a number of one or more surface indexes, wherein the one or more surface indexes define the surfaces where a sound wave originating from the audio source on a certain propagation path is reflected until it arrives (audible) at a listener position.

For example, for a source at position s and a listener at position l, the reflection sequence [5, 18] defines that on a particular propagation path, a sound wave from a source at position s is first reflected at the surface with surface index 5 and then at the surface with surface index 18 until it finally arrives at the position l of the listener (audible, such that the listener can still perceive it). A second reflection sequence may, e.g., be reflection sequence [3, 12]. A third reflection sequence that only comprises [5], indicating that on a particular propagation path, a sound wave from sound source s is only reflected by surface 5 and then arrives audible at the positon/of the listener. A fourth reflection sequence [3, 7] defines that on a particular propagation path, a sound wave from source s is first reflected at the surface with surface index 3 and then at the surface with surface index 7 until it finally arrives audibly at the listener. All reflection sequences for the listener at position l and for the source at position s together define a set of reflection sequences for the listener at position l and for the source at position s.

However, there may, e.g., also be other surfaces defined, for example surfaces with surface indexes 6, 8, 9, 10, 11, or 15 that may, e.g., be located far away from the position l of the listener and far away from the position s of the source. These surfaces will occur less often or not at all in the set of reflection sequences for the listener at the position l and for the source at position s. From this observation it has been found that often, it is advisable to code a set of reflection sequences using entropy coding.

Moreover, even if a plurality of sets of reflection sequences are jointly encoded for a plurality of different listener positions and/or a plurality of different source positions, it may still be advisable to employ entropy coding. For example, in certain listening environments, a user-reachable region may, e.g., be defined, wherein, e.g., the user may, e.g., be assumed to never move through dense bushes or other regions that are not accessible. In some application scenarios, sets of reflection sequences for user positions within these non-accessible regions are not provided. It follows that walls within these regions will usually appear less often in the plurality of sets of reflection sequences, as they are located far away from all defined possible user positions. This results in different occurrences of surface indexes in the plurality of sets of reflection sequences, and thus, entropy encoding these surface indexes in the reflection sets is proposed.

In an embodiment, the actual occurrences of the different values of the additional audio information may, e.g., be observed, and, e.g., based on this observation, either entropy encoding or non-entropy encoding may, e.g., be employed. Using non-entropy encoding when the occurrences of the different values appear with a same or at least roughly similar frequency has inter alia the advantage, that a predefined codeword to symbol relationship may, e.g., be employed that does not have to be transmitted from an encoder to a decoder.

Returning again to more general examples that may also be applied for other application examples than the just described ones:

According to an embodiment, the encoded additional audio information may, e.g., comprise propagation information depending on one or more propagations of one or more sound waves along one or more propagation paths in the real listening environment or in the virtual listening environment or in the augmented listening environment.

In an embodiment, the propagation information may, e.g., be reflection information depending on one or more reflections at one or more reflection objects of one or more sound waves propagating along one or more propagation paths in the real listening environment or in the virtual listening environment or in the augmented listening environment.

According to an embodiment, the propagation information may, e.g., be diffraction information depending on one or more diffractions at one or more diffraction objects of one or more sound waves propagating along one or more propagation paths in the real listening environment or in the virtual listening environment or in the augmented listening environment.

According to an embodiment, the encoded additional audio information may, e.g., comprise data for rendering early reflections. The signal processor 120 may, e.g., be configured to generate the one or more audio output signals depending on the data for rendering early reflections.

In an embodiment, the signal processor 120 may, e.g., be configured to generate a binaural signal comprising two binaural channels as the one or more audio output signals.

According to an embodiment, the at least one entropy decoding module 110 may, e.g., comprise a Huffman decoding module 116 for decoding the encoded additional audio information, when the encoded additional audio information is Huffman-encoded.

In an embodiment, the at least one entropy decoding module 110 may, e.g., comprise an arithmetic decoding module 118 for decoding the encoded additional audio information, when the encoded additional audio information is arithmetically-encoded.

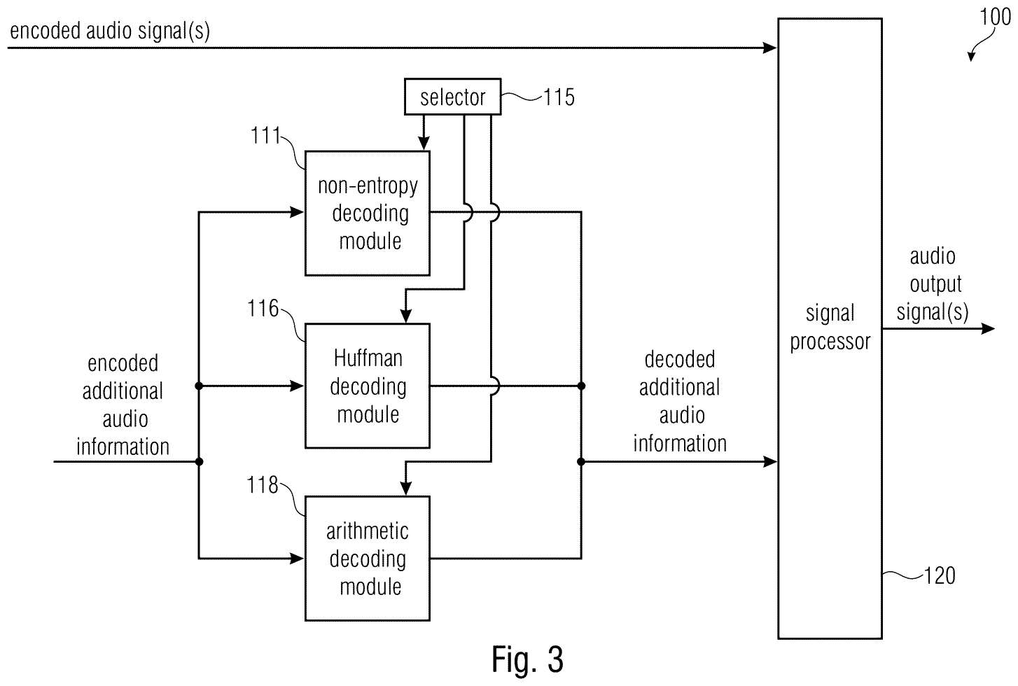

FIG. 3 illustrates an apparatus 100 for generating one or more audio output signals according to another embodiment, wherein the apparatus 100 comprises a non-entropy decoding module 111, a Huffman decoding module 116 and an arithmetic decoding module 118.

The selector 115 may, e.g., be configured to select one of the at least one non-entropy decoding module 111 and of the Huffman decoding module 116 and of the arithmetic decoding module 118 for decoding the encoded additional audio information.

According to an embodiment, the at least one non-entropy decoding module 111 may, e.g., comprise a fixed-length decoding module for decoding the encoded additional audio information, when the encoded additional audio information is fixed-length-encoded.

In an embodiment, the apparatus 100 may, e.g., be configured to receive selection information. The selector 115 may, e.g., be configured to select one of the at least one entropy decoding module 110 and of the at least one non-entropy decoding module 111 depending on the selection information.

According to an embodiment, the apparatus 100 may, e.g., be configured to receive a codebook or a coding tree on which the encoded additional audio information depends. The at least entropy decoding module 110 may, e.g., be configured to decode the encoded additional audio information using the codebook or using the coding tree.

In an embodiment, the apparatus 100 may, e.g., be configured to receive an encoding of a structure of the coding tree on which the encoded additional audio information depends. The at least entropy decoding module 110 may, e.g., be configured to reconstruct a plurality of codewords of the coding tree depending on the structure of the coding tree. Moreover, the at least entropy decoding module 110 may, e.g., be configured to decode the encoded additional audio information using the codewords of the coding tree.

For example, typical coding information that may, e.g., be transmitted from an encoder to a decoder may, e.g., be a codeword list of N elements that comprises all N codewords of the code and a symbol list that comprises all N symbols that are encoded by the N codewords of the code. It may be defined that a codeword at position p with 1≤p≤N of the codeword list encodes the symbol at position p of the symbol list.

For example, content of the following two lists may, e.g., be transmitted, wherein each of the symbols may, for example, represent an surface index identifying a particular surface:

| codeword | 00 | 01 | 10 | 110 | 1110 | 1111 |
|---|---|---|---|---|---|---|
| symbol | 18 | 23 | 15 | 3 | 7 | 9 |

Instead of transmitting the codeword list, however, according to an embodiment, a representation of the coding tree may, e.g., be transmitted from an encoder, which may, e.g., be received by a decoder. The decoder may, e.g., be configured to construct the codeword list from the received representation of the coding tree.

For example, each inner node (e.g., except the root node of the coding tree) may, e.g., be represented by a first bit value (e.g., 0) and each leaf node of the coding tree may, e.g., be represented by a second bit value (e.g., 1).

Considering the above codeword list,

| | | | | | | |
|---|---|---|---|---|---|---|
| codeword | 00 | 01 | 10 | 110 | 1110 | 1111 |

traversing the coding tree from the leftmost branches to the rightmost branches, encoding all new inner nodes when traversing the coding tree with 0, and all leaf nodes when traversing the coding tree with 1, leads to an encoding of a coding tree with the above codewords being represented as:

| | | | | | | |
|---|---|---|---|---|---|---|
| to reach leaf node | 00 | 01 | 10 | 110 | 1110 | 1111 |
| with codeword | | | | | | |
| Bits | 01 | 1 | 01 | 01 | 01 | 1 |

The resulting representation of the coding tree is: 01 1 01 01 01 1.

On the decoder side, the representation of the coding tree can be resolved into a list of codewords:
Codeword 1: First leaf node comes at second node: codeword 1 with bits 00.
Codeword 2: Next, another leaf node follows: codeword 2 with bits: 01.
Codeword 3: All nodes on the left side of the root node have been found, continue with the right branch of the root node: the first leaf on the right side of the root node is at the second node: codeword 3 with bits “10”
Codeword 4: Ascend one node upwards (under first branch 1). Descend into the right branch (second branch 1), an inner node (0); move into the left branch (branch 0), a leaf node (1): codeword 4: “110”. (leaf node under branches 1-1-0)
Codeword 5: Ascend one node upwards (under second branch 1). Descend into the right branch (third branch 1), an inner node (0); move into the left branch (branch 0), a leaf node (1): codeword 5: “1110” (leaf node under branches 1-1-1-0)
Codeword 6: Ascend one node upwards Descend into the right branch (fourth branch 1), this is a leaf node (1): codeword 6: “1111” (leaf node under branches 1-1-1-1).

By coding the coding tree structure instead of the codewords, coding efficiency is increased.

In an embodiment, the apparatus 100 may, e.g., further comprise a memory having stored thereon a codebook or a coding tree. The at least entropy decoding module 110 may, e.g., be configured to decode the encoded additional audio information using the codebook or using the coding tree.

According to an embodiment, the apparatus 100 may, e.g., be configured to receive the encoded additional audio information comprising a plurality of transmitted symbols and an offset value. The at least one non-entropy decoding module 111 may, e.g., be configured to decode the encoded additional audio information using the plurality of transmitted symbols and using the offset value.

In an embodiment, the data for rendering early reflections may, e.g., comprise information on a location of one or more walls, being one or more real walls or virtual walls in an environment. The signal processor 120 may, e.g., be configured to generate the one or more audio output signals depending on the information on the location of one or more walls.

According to an embodiment, the information on each wall of the one or more walls may, e.g., comprise information on a azimuth angle and/or an elevation angle of said wall, wherein the azimuth angle of said wall may, e.g., be entropy-encoded and/or the elevation angle of said wall may, e.g., be entropy-encoded. One or more entropy decoding modules of the at least one entropy decoding module 110 are configured to decode an entropy-encoded azimuth angle of said wall and/or an entropy-encoded elevation angle of said wall.

In an embodiment, said one or more of the at least one entropy decoding module 110 are configured to decode the entropy-encoded azimuth angle of said wall and/or the entropy-encoded elevation angle of said wall using the codebook or the coding tree.

According to an embodiment, the encoded additional audio information may, e.g., comprise voxel position information, wherein the position information may, e.g., comprise information on one or more positions of one or more voxels out of a plurality of voxels within a three-dimensional coordinate system. The signal processor 120 may, e.g., be configured to generate the one or more audio output signals depending on the voxel position information.

In an embodiment, the at least one entropy decoding module 110 may, e.g., be configured to decode encoded additional audio information being entropy-encoded, wherein the encoded additional audio information being entropy-encoded may, e.g., comprise at least one of the following:
a list of triangle indexes, for example, earlySurfaceFaceIdx,
an array length of a list of triangle indexes, for example, an array length of earlySurfaceFaceIdx, for example, earlySurfaceLengthFaceIdx,
an array with azimuth angles specifying surface normals in spherical coordinates (for example, in Hesse normal form), for example, earlySurfaceAzi,
an array with elevation angles specifying surface normals in spherical coordinates (for example, in Hesse normal form), for example, earlySurfaceEle,
an array with distance values (for example, in Hesse normal form), for example, earlySurfaceDist,
an array with positions of a listener, for example, an array with listener voxel indices, for example, earlyVoxelL,
an array with positions of one or more sound sources, for example, an array with source voxel indices, for example, earlyVoxelS,
a removal list or a removal set, for example, a differentially encoded removal list or a differentially encoded removal set, specifying indices of reflection sequences of a set of reflection sequences that shall be removed or a reference reflection sequence list that shall be removed, for example, earlyVoxelIndicesRemovedDiff,
a number of reflection sequences or a number of reflection paths, for example, earlyVoxelNumPaths
an array, for example, a two-dimensional array, specifying a reflection order, for example, earlyVoxelOrder
reflection sequences, for example, earlyVoxelSurf.

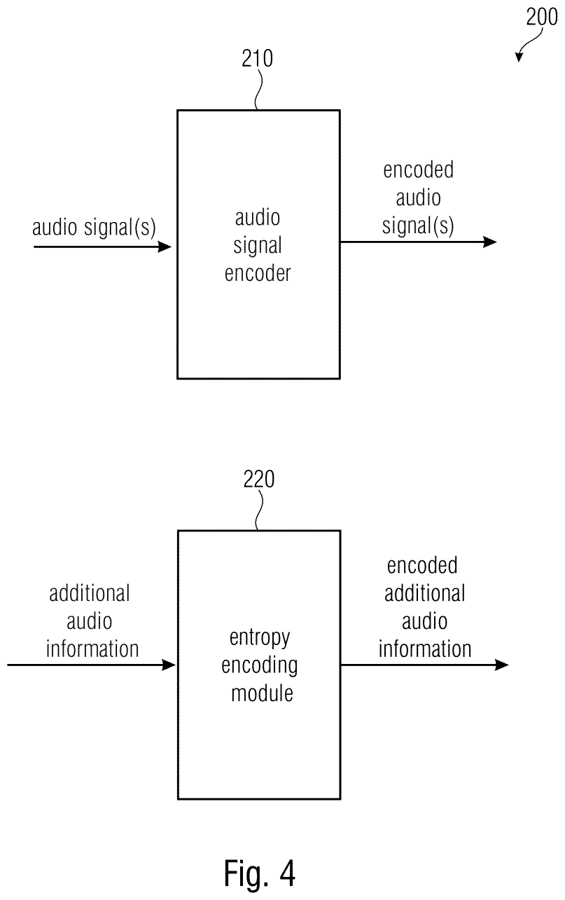

FIG. 4 illustrates an apparatus 200 for encoding one or more audio signals and additional audio information according to an embodiment.

The apparatus 200 comprises an audio signal encoder 210 for encoding the one or more audio signals to obtain one or more encoded audio signals.

Furthermore, the apparatus 200 comprises at least one entropy encoding module 220 for encoding the additional audio information using entropy encoding to obtain encoded additional audio information.

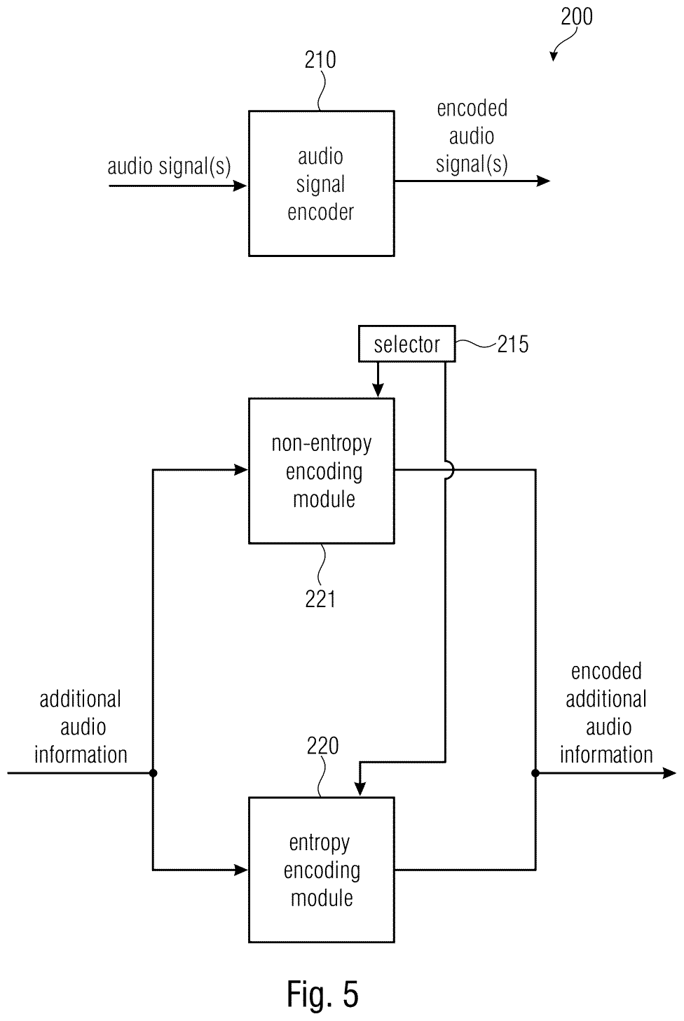

FIG. 5 illustrates an apparatus 200 for encoding one or more audio signals and additional audio information according to another embodiment. Compared to the apparatus 200 of FIG. 4, the apparatus 200 of FIG. 4 further comprises at least one non-entropy encoding module 221 and a selector 215.

The at least one non-entropy encoding module 221 may, e.g., be configured to encode the additional audio information to obtain the encoded additional audio information, and

The selector 215 may, e.g., be configured to select one of the at least one entropy encoding module 220 and of the at least one non-entropy encoding module 221 for encoding the additional audio information depending on a symbol distribution within the additional audio information that is to be encoded.

According to an embodiment, the encoded additional audio information may, e.g., comprise augmented reality data or virtual reality data.

In an embodiment, the encoded additional audio information depends on a real listening environment or depends on a virtual listening environment or depends on an augmented listening environment.

According to an embodiment, the additional audio information may, e.g., comprise propagation information depending on one or more propagations of one or more sound waves along one or more propagation paths in the real listening environment or in the virtual listening environment or in the augmented listening environment.

In an embodiment, the propagation information may, e.g., be reflection information depending on one or more reflections at one or more reflection objects of one or more sound waves propagating along one or more propagation paths in the real listening environment or in the virtual listening environment or in the augmented listening environment.

According to an embodiment, the propagation information may, e.g., be diffraction information depending on one or more diffractions at one or more diffraction objects of one or more sound waves propagating along one or more propagation paths in the real listening environment or in the virtual listening environment or in the augmented listening environment.

According to an embodiment, the encoded additional audio information may, e.g., comprise data for rendering early reflections.

In an embodiment, the at least one entropy encoding module 220 may, e.g., comprise a Huffman encoding module 226 for encoding the additional audio information using Huffman encoding.

According to an embodiment, the at least one entropy encoding module 220 may, e.g., comprise an arithmetic encoding module 228 for encoding the additional audio information using arithmetic encoding.

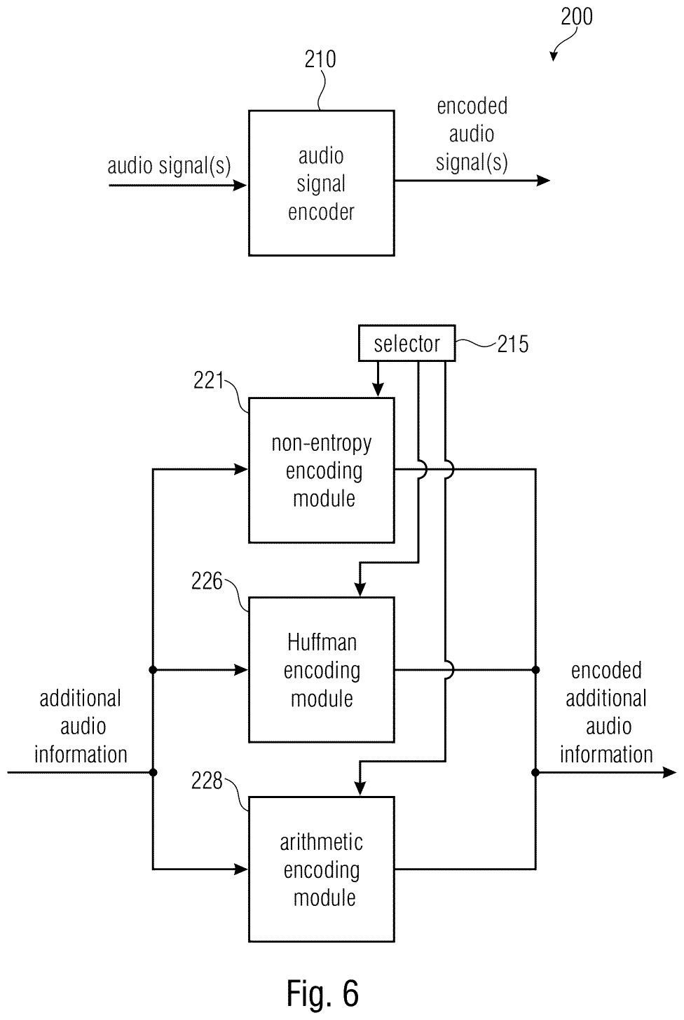

FIG. 6 illustrates an apparatus 200 for generating one or more audio output signals according to another embodiment, wherein the apparatus 200 comprises a non-entropy encoding module 221, a Huffman encoding module 226 and an arithmetic encoding module 228.

The selector 215 may, e.g., be configured to select one of the at least one non-entropy encoding module 221 and of the Huffman encoding module 226 and of the arithmetic encoding module 228 for encoding the additional audio information.

In an embodiment, the at least one non-entropy encoding module 221 may, e.g., comprise a fixed-length encoding module for encoding the additional audio information.

According to an embodiment, the apparatus 200 may, e.g., be configured to generate selection information indicating one of the at least one entropy encoding module 220 and of the at least one non-entropy encoding module 221 which has been employed for encoding the additional audio information.

In an embodiment, the apparatus 200 may, e.g., be configured to transmit a codebook or a coding tree which has been employed to encode the additional audio information.

In an embodiment, the apparatus 200 may, e.g., be configured to transmit an encoding of a structure of the coding tree on which the encoded additional audio information depends.

According to an embodiment, the apparatus 200 may, e.g., further comprise a memory having stored thereon a codebook or a coding tree. The at least entropy encoding module 220 may, e.g., be configured to encode the additional audio information using the codebook or using the coding tree.

In an embodiment, the at least one entropy encoding module 220 may, e.g., be configured to encode the additional audio information such that the encoded additional audio information may, e.g., comprise a plurality of transmitted symbols and an offset value.

According to an embodiment, the data for rendering early reflections may, e.g., comprise information on a location of one or more walls, being one or more real walls or virtual walls in an environment.

In an embodiment, the information on each wall of the one or more walls may, e.g., comprise information on a azimuth angle and/or an elevation angle of said wall, wherein the azimuth angle of said wall may, e.g., be entropy-encoded and/or the elevation angle of said wall may, e.g., be entropy-encoded. One or more entropy encoding modules of the at least one entropy encoding module 220 are configured to encode the additional audio information such that the encoded additional audio information may, e.g., comprise an entropy-encoded azimuth angle of said wall and/or an entropy-encoded elevation angle of said wall.

According to an embodiment, said one or more entropy encoding modules are configured to encode the entropy-encoded azimuth angle of said wall and/or the entropy-encoded elevation angle of said wall using the codebook or the coding tree.

In an embodiment, the encoded additional audio information may, e.g., comprise voxel position information, wherein the position information may, e.g., comprise information on one or more positions of one or more voxels out of a plurality of voxels within a three-dimensional coordinate system.

According to an embodiment, the at least one entropy encoding module 220 may, e.g., be configured to encode the additional audio information using entropy encoding, wherein the encoded additional audio information may, e.g., comprise at least one of the following:
a list of triangle indexes, for example, earlySurfaceFaceIdx,
an array length of a list of triangle indexes, for example, an array length of earlySurfaceFaceIdx, for example, earlySurfaceLengthFaceIdx,
an array with azimuth angles specifying surface normals in spherical coordinates (for example, in Hesse normal form), for example, earlySurfaceAzi,
an array with elevation angles specifying surface normals in spherical coordinates (for example, in Hesse normal form), for example, earlySurfaceEle,
an array with distance values (for example, in Hesse normal form), for example, earlySurfaceDist,
an array with positions of a listener, for example, an array with listener voxel indices, for example, earlyVoxelL,
an array with positions of one or more sound sources, for example, an array with source voxel indices, for example, earlyVoxelS,
a removal list or a removal set, for example, a differentially encoded removal list or a differentially encoded removal set, specifying indices of reflection sequences of a set of reflection sequences that shall be removed or a reference reflection sequence list that shall be removed, for example, earlyVoxelIndicesRemovedDiff,
a number of reflection sequences or a number of reflection paths, for example, earlyVoxelNumPaths
an array, for example, a two-dimensional array, specifying a reflection order, for example, earlyVoxelOrder
reflection sequences, for example, earlyVoxelSurf.

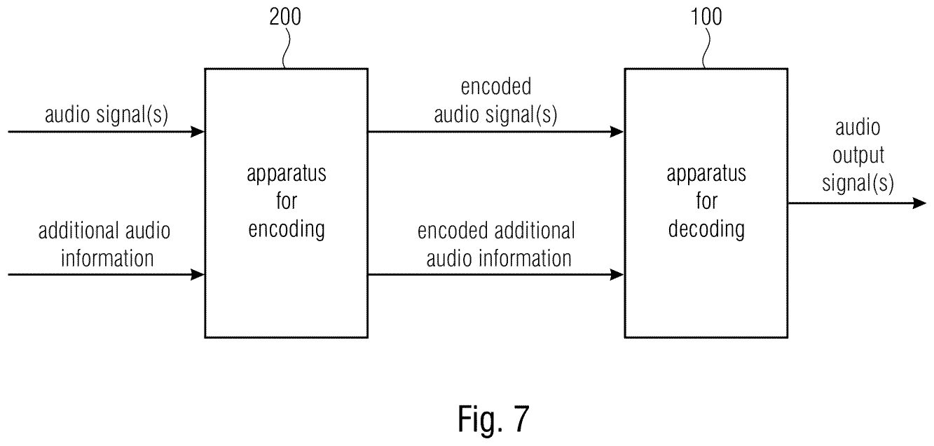

FIG. 7 illustrates a system according to an embodiment. The system comprises the apparatus 200 of FIG. 4 for encoding one or more audio signals and additional audio information to obtain one or more encoded audio signals and encoded additional audio information. Moreover, the system comprises the apparatus 100 of FIG. 1 for generating one or more audio output signals from the one or more encoded audio signals depending on the encoded additional audio information.

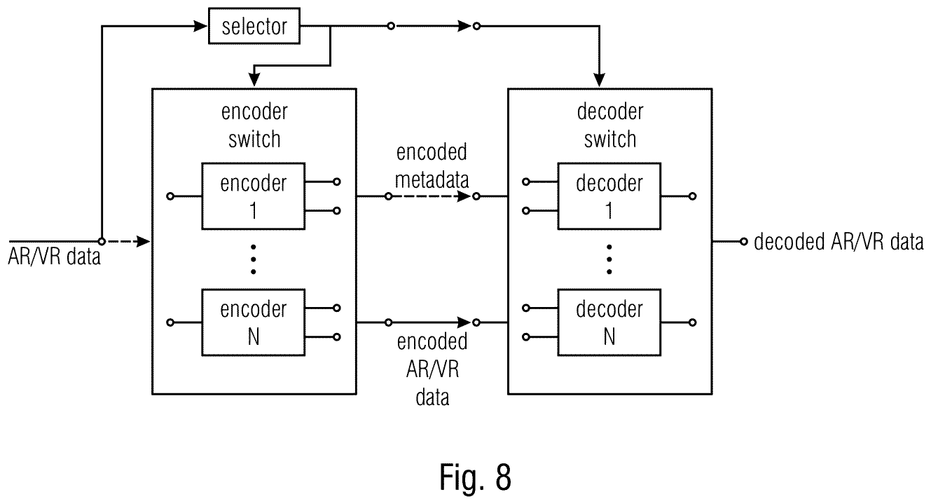

FIG. 8 illustrates a particular embodiment which depicts encoding of the additional audio data and decoding of the encoded additional audio data. In FIG. 8 the additional audio data is AR data or VR data, which is encoded on an encoder side to obtain encoded AR data or VR data. Metadata may also be encoded. The encoded AR data or the encoded VR data is then decoder on the decoder side to obtain decoded AR data or decoded VR data. On the encoder side, a selector steers an encoder switch to select one of N different encoder modules for encoding the AR data or VR data. In FIG. 8, the selector provides information to the decoder side such that the corresponding decoding module out of N decoding modules is selected for decoding the encoded AR data or the encoded VR data.

In the following, further embodiments are provided.

According to an embodiment, a system for encoding and decoding data series having an encoder sub-system and a decoder sub-system is provided. The encoder sub-system may, e.g., comprise at least two different encoding methods, an encoder selector, and an encoder switch which chooses one of the encoding methods. The encoder sub-system may, e.g., transmit the chosen selection, encoding parameters of the chosen encoder, and data encoded by the chosen encoder. The decoder sub-system may, e.g., comprise the corresponding decoders and a decoder switch which selects one of the decoding methods.

In an embodiment, the data series may, e.g., comprise AR/VR data.

According to an embodiment, the data series may, e.g., comprise metadata for rendering early reflections.

In an embodiment, at least one fixed length encoder/decoder may, e.g., be used and at least one variable length encoder/decoder may, e.g., be used.

According to an embodiment, one of the variable length encoders/decoders is a Huffman encoder/decoder.

In an embodiment, the encoding parameters may, e.g., include a codebook or a decoding tree.

According an embodiment, the encoding parameters may, e.g., include an offset value and where a combination of this offset value and the transmitted symbols yields the decoded data series.

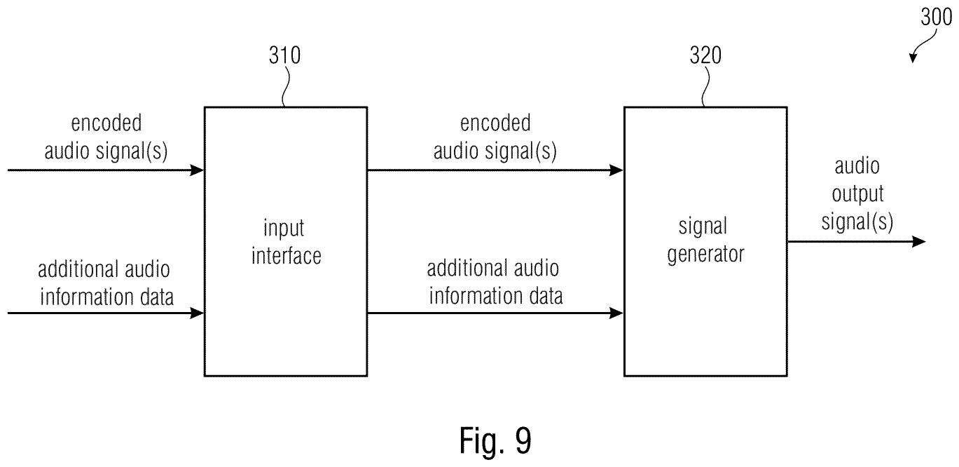

FIG. 9 illustrates an apparatus 300 for generating one or more audio output signals from one or more encoded audio signals according to another embodiment.

The apparatus 300 comprises an input interface 310 for receiving the one or more encoded audio signals and for receiving additional audio information data.

Furthermore, the apparatus 300 comprises a signal generator 320 for generating the one or more audio output signals depending on the encoded audio signals and depending on second additional audio information.

The signal generator 320 is configured to obtain the second additional audio information using the additional audio information data and using first additional audio information, if the additional audio information data exhibits a redundancy state.

Moreover, the signal generator 320 is configured to obtain the second additional audio information using the additional audio information data without using the first additional audio information, if the additional audio information data exhibits a non-redundancy state.

According to an embodiment, the input interface 310 may, e.g., be configured to receive propagation information data as the additional audio information data. The signal generator 320 may, e.g., be configured to generate the one or more audio output signals depending on the second additional audio information, being second propagation information.

Moreover, the signal generator 320 may, e.g., be configured to obtain the second propagation information using the propagation information data and using the first additional audio information, being first propagation information, if the propagation information data exhibits a redundancy state. Furthermore, the signal generator 320 may, e.g., be configured to obtain the second propagation information using the propagation information data without using the first propagation information, if the propagation information data exhibits a non-redundancy state.

According to an embodiment, the first propagation information and/or the second propagation information may, e.g., depend on one or more propagations of one or more sound waves along one or more propagation paths in a real listening environment or in a virtual listening environment or in an augmented listening environment.

In an embodiment, the propagation information data may, e.g., comprise reflection information data and/or diffraction information data. The first propagation information may, e.g., comprise first reflection information and/or first diffraction information. Moreover, the second propagation information may, e.g., comprise second reflection information and/or second diffraction information.

According to an embodiment, the input interface 310 may, e.g., be configured to receive reflection information data as the propagation information data. The signal generator 320 may, e.g., be configured to generate the one or more audio output signals depending on the second propagation information, being second reflection information. Moreover, the signal generator 320 may, e.g., be configured to obtain the second reflection information using the reflection information data and using the first propagation information, being first reflection information, if the reflection information data exhibits a redundancy state. Furthermore, the signal generator 320 may, e.g., be configured to obtain the second reflection information using the reflection information data without using the first reflection information, if the reflection information data exhibits a non-redundancy state.

In an embodiment, the first reflection information and/or the second reflection information may, e.g., depend on one or more reflections at one or more reflection objects of one or more sound waves propagating along one or more propagation paths in the real listening environment or in the virtual listening environment or in the augmented listening environment.

The first and the second reflection information may, e.g., comprise the sets of reflection sequences described above. As already outlined, example, for a given audio source position s and, e.g., for a given listener position l, a reflection sequence may, e.g., define a number of one or more surfaces identified by a number of one or more surface indexes defines the surfaces where a sound wave originating from the audio source on a certain propagation path is reflected until it arrives (audible) at a listener position.

All these reflection sequences defined for a listener at position l and for a source at position s form a set of reflection sequences.

It has been found that, for example, for neighbouring listener positions, the sets of reflection sequences are quite similar. It is thus proposed that an encoder encodes only those reflection sequences (e.g., in reflection information data) that are not comprised by a similar set of reflection sequences (e.g., in the first reflection information) and only indicates those reflection sequences of the similar set of reflection sequences of the similar set of reflection sequences that are not valid for the current set of reflection sequences. Likewise, the respective decoder obtains the current set of reflection sequences (e.g., the second reflection information) from the similar set of reflection sequences (e.g., the first reflection information) using the received reduced information (e.g., the reflection information data).

In an embodiment, the input interface 310 may, e.g., be configured to receive diffraction information data as the propagation information data. The signal generator 320 may, e.g., be configured to generate the one or more audio output signals depending on the second propagation information, being second diffraction information. Moreover, the signal generator 320 may, e.g., be configured to obtain the second diffraction information using the diffraction information data and using the first propagation information, being first diffraction information, if the diffraction information data exhibits a redundancy state. Furthermore, the signal generator 320 may, e.g., be configured to obtain the second diffraction information using the diffraction information data without using the first diffraction information, if the diffraction information data exhibits a non-redundancy state.

According to an embodiment, the first diffraction information and/or the second diffraction information may, e.g., depend on one or more diffractions at one or more diffraction objects of one or more sound waves propagating along one or more propagation paths in the real listening environment or in the virtual listening environment or in the augmented listening environment.

For example, the first and the second diffraction information may, e.g., comprise a set of diffraction sequences for a listener at position l and for a source at position s. A set of diffraction sequences may, e.g., be defined analogously as the set of reflection sequences but relates to diffraction objects (e.g., objects that cause diffraction) rather than to reflection objects. Often, the diffraction objects and the reflection objects may, e.g., be the same objects. When these objects are considered as reflection objects, the surfaces of these objects are considered, while, when these objects are considered as diffraction objects, the edges of these objects are considered for diffraction.

According to an embodiment, if the propagation information data exhibits the redundancy state, the propagation information data may, e.g., indicate one or more propagation sequences that are to be removed from the first propagation information, being a first set of propagation sequences, and/or may, e.g., indicate one or more propagation sequences that are to be added to the first set of propagation sequences to obtain the second propagation information, being a second set of propagation sequences. The signal generator 320 may, e.g., be configured to update the first set of propagation sequences using the propagation information data to obtain the second set of propagation sequences.

In an embodiment, each reflection sequence of the first set of reflection sequences and of the second set of reflection sequences may, e.g., indicate a group of one or more reflection objects or a group of one or more diffraction objects.

In an embodiment, if the propagation information data exhibits the non-redundancy state, the propagation information data may, e.g., comprise the second set of propagation sequences, and the signal generator 320 may, e.g., be configured to determine the second set of propagation sequences from the propagation information data.

According to an embodiment, the first set of propagation sequences may, e.g., be associated with a first listener position and with a first source position. The second set of propagation sequences may, e.g., be associated with a second listener position and with a second source position. The first listener position may, e.g., be different from the second listener position, and/or wherein the first source position may, e.g., be different from the second source position.

In an embodiment, the first set of propagation sequences may, e.g., be a first set of reflection sequences. The second set of propagation sequences may, e.g., be a second set of reflection sequences. Each reflection sequence of the first set of reflection sequences may, e.g., comprise information on the group of one or more reflection objects of the reflection sequence, where sound waves emitted by an audio source at the first source position and perceivable by a listener at the first listener position are reflected on their way to the current listener location. Each reflection sequence of the second set of reflection sequences may, e.g., comprise information on the group of one or more reflection objects of the reflection sequence, where sound waves emitted by an audio source at the second source position and perceivable by a listener at the second listener position are reflected on their way to the current listener location.

According to an embodiment, the one or more encoded audio signals are associated with the audio source being located at the source position of the second set of reflection sequences. The signal generator 320 may, e.g., be configured to generate the one or more audio output signals using the one or more encoded audio signals and using the second set of reflection sequences such that the one or more audio output signals may, e.g., comprise early reflections of the sound waves emitted by the audio source at the source position of the second set of reflection sequences.

In an embodiment, the input interface 310 may, e.g., be configured to receive reflection information data as the propagation information data. The signal generator 320 may, e.g., be configured to obtain a plurality of sets of reflection sequences, wherein each of the plurality of sets of reflection sequences may, e.g., be associated with a listener position and with a source position. The input interface 310 may, e.g., be configured to receive an indication. For determining the second set of reflection sequences, the signal generator 320 may, e.g., be configured, if the reflection information data exhibits the redundancy state, to determine the first listener position and the first source position using the indication, and to choose that one of the plurality of sets of reflection sequences as the first set of reflection sequences which is associated with the first listener position and with the first source position.

For example, each reflection sequence of each set of reflection sequences of the plurality of sets of reflection sequences may, e.g., comprise information on the group of one or more reflection objects of the reflection sequence, where sound waves emitted by an audio source at the source position of said set of reflection sequences and perceivable by a listener at the listener position of the said set of reflection sequences are reflected on their way to the current listener location.

According to an embodiment, if the reflection information data exhibits a redundancy state, the indication may, e.g., indicate to choose the first listener position and the first source position, such that the first listener position is neighboured to the second listener position and/or such that the first source position is neighboured to the second listener positon. If the reflection information data exhibits a redundancy state, the signal generator 320 may, e.g., be configured to determine the first listener position and/or the first source position according to the indication.

In an embodiment, if the reflection information data exhibits a redundancy state, the indication may, e.g., indicate to choose the first listener position and the first source position, such that the first listener position is neighboured to the second listener position and such that the first source position is identical with the second listener position. The signal generator 320 is configured to determine the first listener position and the first source position according to the indication.

Or, in an embodiment, if the reflection information data exhibits a redundancy state, the indication may, e.g., indicate to choose the first listener position and the first source position, such that the first listener position is identical with the second listener position and such that the first source position is neighboured to the second listener position. The signal generator 320 may, e.g., be configured to determine the first listener position and the first source position according to the indication.

According to an embodiment, in a coordinate system, a first position and a second position are neighboured, if in each coordinate direction of the coordinate system, the first position immediately precedes or immediately succeeds the second position or is identical to the second position, and if in at least one coordinate direction of the coordinate system, the first position and the second position are different from each other.

In an embodiment, the indication may, e.g., indicate one of the following:
that the reflection information data exhibits the non-redundancy state,
that the reflection information data exhibits a first redundancy state, so that the first listener position and the first source position shall be chosen, such that the first source position is identical with the second source position, and such that the first listener position is neighboured to the second listener position, wherein in a first coordinate direction of a coordinate system, the first listener position immediately precedes the second listener position, and wherein in a second coordinate direction and in a third coordinate direction of the coordinate system, the first listener position is identical with the second listener position,
that the reflection information data exhibits a second redundancy state, so that the first listener position and the first source position shall be chosen, such that the first source position is identical with the second source position, and such that the first listener position is neighboured to the second listener position, wherein in the second coordinate direction of the coordinate system, the first listener position immediately precedes the second listener position, and wherein in the first coordinate direction and in the third coordinate direction of the coordinate system, the first listener position is identical with the second listener position,
that the reflection information data exhibits a third redundancy state, so that the first listener position and the first source position shall be chosen, such that the first source position is identical with the second source position, and such that the first listener position is neighboured to the second listener position, wherein in the third coordinate direction of the coordinate system, the first listener position immediately precedes the second listener position, and wherein in the first coordinate direction and in the second coordinate direction of the coordinate system, the first listener position is identical with the second listener position.

If the indication indicates the first redundancy state or the second redundancy state or the first redundancy state, the signal generator 320 may, e.g., be configured to determine the first listener position and the first source position according to the indication.

According to an embodiment, each of the first listener position, the first source position, the second listener position and the second source position may, e.g., defines a position of a voxel out of a plurality of voxels within a three-dimensional coordinate system.

For example, each of the listener position and the source position of each of the plurality of sets of reflection sequences may, e.g., define a position of a voxel out of a plurality of voxels within a three-dimensional coordinate system.

In an embodiment, the signal generator 320 may, e.g., be configured to generate a binaural signal comprising two binaural channels as the one or more audio output signals.

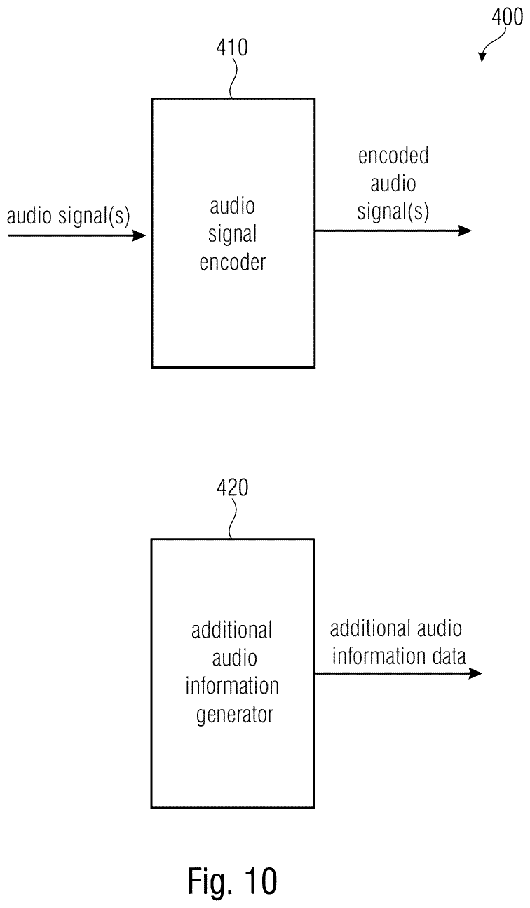

FIG. 10 illustrates an apparatus 400 for encoding one or more audio signals and for generating additional audio information data according to an embodiment.

The apparatus 400 comprises an audio signal encoder 410 for encoding the one or more audio signals to obtain one or more encoded audio signals.

Furthermore, the apparatus 400 comprises an additional audio information generator 420 for generating the additional audio information data, wherein the additional audio information generator 420 exhibits a non-redundancy operation mode and a redundancy operation mode.

The additional audio information generator 420 is configured to generate the additional audio information data, if the additional audio information generator 420 exhibits the non-redundancy operation mode, such that the additional audio information data comprises the second additional audio information.

Moreover, the additional audio information generator 420 is configured to generate the additional audio information data, if the additional audio information generator 420 exhibits the non-redundancy operation mode, such that the additional audio information data does not comprise the second additional audio information or does only comprise a portion of the second additional audio information, such that the second additional audio information is obtainable using the additional audio information data together with first additional audio information.

According to an embodiment, the additional audio information generator 420 may, e.g., be a propagation information generator for generating propagation information data as the additional audio information data. The propagation information generator may, e.g., be configured to generate the propagation information data, if the propagation information generator exhibits the non-redundancy operation mode, such that the propagation information data comprises the second additional audio information being second propagation information. Moreover, the propagation information generator may, e.g., be configured to generate the propagation information data, if the propagation information generator exhibits the non-redundancy operation mode, such that the propagation information data does not comprise the second propagation information or does only comprise a portion of the second propagation information, such that the second propagation information is obtainable using the propagation information data together with first propagation information.

According to an embodiment, the first propagation information and/or the second propagation information may, e.g., depend on one or more propagations of one or more sound waves along one or more propagation paths in a real listening environment or in a virtual listening environment or in an augmented listening environment.

In an embodiment, the propagation information data may, e.g., comprise reflection information data and/or diffraction information data. The first propagation information may, e.g., comprise first reflection information and/or first diffraction information. The second propagation information may, e.g., comprise second reflection information and/or second diffraction information.

According to an embodiment, the propagation information generator may, e.g., be a reflection information generator for generating reflection information data as the propagation information data. The reflection information generator may, e.g., be configured to generate the reflection information data, if the reflection information generator exhibits the non-redundancy operation mode, such that the reflection information data comprises second reflection information as the second propagation information. Moreover, the reflection information generator may, e.g., be configured to generate the reflection information data, if the reflection information generator exhibits the non-redundancy operation mode, such that the reflection information data does not comprise the second reflection information or does only comprise a portion of the second reflection information, such that the second reflection information is obtainable using the reflection information data together with the first propagation information being first reflection information.

In an embodiment, the first reflection information and/or the second reflection information may, e.g., depend on one or more reflections at one or more reflection objects of one or more sound waves propagating along one or more propagation paths in the real listening environment or in the virtual listening environment or in the augmented listening environment.

According to an embodiment, the propagation information generator may, e.g., be a diffraction information generator for generating diffraction information data as the propagation information data. The diffraction information generator may, e.g., be configured to generate the diffraction information data, if the diffraction information generator exhibits the non-redundancy operation mode, such that the diffraction information data comprises second diffraction information as the second propagation information. Moreover, the diffraction information generator may, e.g., be configured to generate the diffraction information data, if the diffraction information generator exhibits the non-redundancy operation mode, such that the diffraction information data does not comprise the second diffraction information or does only comprise a portion of the second diffraction information, such that the second diffraction information is obtainable using the diffraction information data together with the first propagation information being first diffraction information.

In an embodiment, the first diffraction information and/or the second diffraction information may, e.g., depend on one or more diffractions at one or more diffraction objects of one or more sound waves propagating along one or more propagation paths in the real listening environment or in the virtual listening environment or in the augmented listening environment.

According to an embodiment, the propagation information generator may, e.g., be configured in the redundancy operation mode to generate the propagation information data such that the propagation information data may, e.g., indicate one or more propagation sequences that are to be removed from the first propagation information, being a first set of propagation sequences, and/or may, e.g., indicate one or more propagation sequences that are to be added to the first set of propagation sequences to obtain the second propagation information, being a second set of propagation sequences.

In an embodiment, each propagation sequence of the first set of propagation sequences and of the second set of propagation sequences may, e.g., indicate a group of one or more reflection objects or a group of one or more diffraction objects.

In an embodiment, the propagation information generator may, e.g., be configured in the non-redundancy operation mode to generate the propagation information data such that the propagation information data may, e.g., comprise the second set of propagation sequences.

According to an embodiment, the first set of propagation sequences may, e.g., be associated with a first listener position and with a first source position. The second set of propagation sequences may, e.g., be associated with a second listener position and with a second source position. The first listener position may, e.g., be different from the second listener position, and/or wherein the first source position may, e.g., be different from the second source position.

In an embodiment, the first set of propagation sequences may, e.g., be a first set of reflection sequences. The propagation information generator may, e.g., be a reflection information generator. The second set of propagation sequences may, e.g., be a second set of reflection sequences. The propagation information data may, e.g., be reflection information data. Each reflection sequence of the first set of reflection sequences may, e.g., comprise information on the group of one or more reflection objects of the reflection sequence, where sound waves emitted by an audio source at the first source position and perceivable by a listener at the first listener position are reflected on their way to the current listener location. The reflection information generator may, e.g., be configured to generate the reflection information data such that each reflection sequence of the second set of reflection sequences may, e.g., comprise information on the group of one or more reflection objects of the reflection sequence, where sound waves emitted by an audio source at the second source position and perceivable by a listener at the second listener position are reflected on their way to the current listener location.

According to an embodiment, the one or more encoded audio signals are associated with the audio source being located at the source position of the second set of reflection sequences.

In an embodiment, the reflection information generator may, e.g., be configured in the redundancy operation mode to generate an indication suitable for determining the first listener position and the first source position of the first set of reflection sequences.

According to an embodiment, the reflection information generator may, e.g., be configured in the redundancy operation mode to generate the indication such that the indication may, e.g., indicate to choose the first listener position and the first source position, such that the first listener position is neighboured to the second listener position and/or such that the first source position is neighboured to the second listener positon.

In an embodiment, the reflection information generator may, e.g., be configured in the redundancy operation mode to generate the indication such that the indication may, e.g., indicate to choose the first listener position and the first source position, such that the first listener position is neighboured to the second listener position and such that the first source position is identical with the second listener position.

Or, in an embodiment, the reflection information generator may, e.g., be configured in the redundancy operation mode to generate the indication such that the indication may, e.g., indicate to choose the first listener position and the first source position, such that the first listener position is identical with the second listener position and such that the first source position is neighboured to the second listener position.

According to an embodiment, in a coordinate system, a first position and a second position are neighboured, if in each coordinate direction of the coordinate system, the first position immediately precedes or immediately succeeds the second position or is identical to the second position, and if in at least one coordinate direction of the coordinate system, the first position and the second position are different from each other.

In an embodiment, the reflection information generator may, e.g., be configured in the redundancy operation mode to generate the indication such that the indication may, e.g., indicate one of the following:
that the reflection information data exhibits the non-redundancy state,
that the reflection information data exhibits a first redundancy state, so that the first listener position and the first source position shall be chosen, such that the first source position is identical with the second source position, and such that the first listener position is neighboured to the second listener position, wherein in a first coordinate direction of a coordinate system, the first listener position immediately precedes the second listener position, and wherein in a second coordinate direction and in a third coordinate direction of the coordinate system, the first listener position is identical with the second listener position,
that the reflection information data exhibits a second redundancy state, so that the first listener position and the first source position shall be chosen, such that the first source position is identical with the second source position, and such that the first listener position is neighboured to the second listener position, wherein in the second coordinate direction of the coordinate system, the first listener position immediately precedes the second listener position, and wherein in the first coordinate direction and in the third coordinate direction of the coordinate system, the first listener position is identical with the second listener position,
that the reflection information data exhibits a third redundancy state, so that the first listener position and the first source position shall be chosen, such that the first source position is identical with the second source position, and such that the first listener position is neighboured to the second listener position, wherein in the third coordinate direction of the coordinate system, the first listener position immediately precedes the second listener position, and wherein in the first coordinate direction and in the second coordinate direction of the coordinate system, the first listener position is identical with the second listener position.

According to an embodiment, each of the first listener position, the first source position, the second listener position and the second source position may, e.g., define a position of a voxel out of a plurality of voxels within a three-dimensional coordinate system.

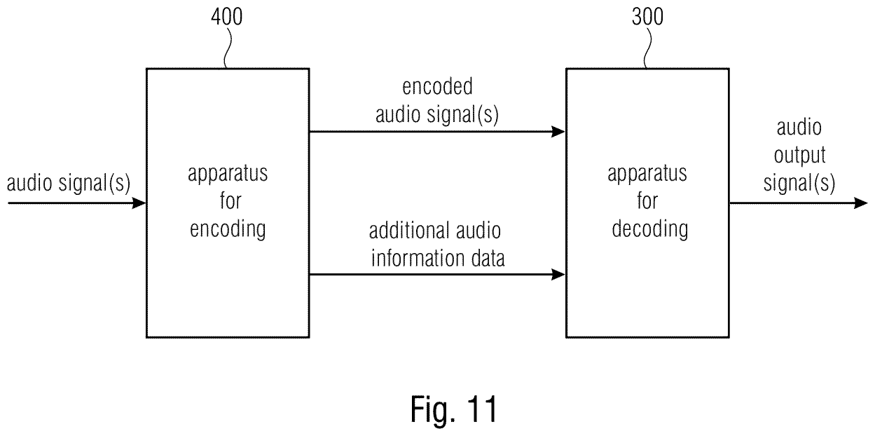

FIG. 11 illustrates a system according to another embodiment. The system comprises the apparatus 400 of FIG. 10 for encoding one or more audio signals to obtain one or more encoded audio signals and for generating additional audio information data. Moreover, the system comprises the apparatus 300 of FIG. 9 for generating one or more audio output signals from the one or more encoded audio signals depending on the additional audio information data.

In the following, further particular embodiments are provided.

More particularly, binary encoding and decoding of metadata is considered.

The current working draft for the MPEG-I 6DoF Audio specification (“first draft version of RM0”) states that earlySurfaceDataJSON, earlySurfaceConnectedDataJSON, and earlyVoxelDataJSON are represented as a “zero terminated character string in ASCII encoding. This string contains a JSON formatted document as provisional data format”. In this input document we are proposing to replace this provisional data format by a binary data format using an encoding method which results in significantly smaller bitstream sizes.

This Core Experiment is based on the first draft version of RM0. It aims at replacing the JSON formatted early reflection metadata by a binary encoding format. By applying particular techniques, substantial reductions of the size of the early reflection payload achieved while introducing insignificant quantization errors.

The techniques applied to reduce the payload size comprise:
1. Data consolidation: Variables which are no longer used by the RefSoft renderer earlySurfaceConnectedData) are removed.
2. Coordinate system: The unit normal vector of the reflection planes are transmitted in spherical coordinates instead of Cartesian coordinates to reduce the number of coefficients from 3 to 2.
3. Quantization: The coefficients which define the reflection planes are quantized with high resolution (quasi lossless coding).
4. Entropy encoding: A codebook based general purpose encoding schema is used for entropy coding of the transmitted symbols. The applied method is beneficial specially for data series with a very large number of symbols while also being suitable for a small number of symbols.
5. Inter-voxel redundancy reduction: The similarity of voxel data of voxel neighbors is exploited to further reduce the bitstream size. A differential approach is used where the differences between the current voxel data set and a neighbor voxel data set is encoded.

The decoder is simplified since a parsing step of the JSON data is no longer needed while the runtime complexity of the renderer is not affected by the proposed changes.

Furthermore, the proposed replacement also reduces the library dependencies of the renderer as well as the library dependencies of the encoder since generating and parsing JSON documents is no longer needed.

For all “test 1” and “test 2” scenes, the proposed encoding method provides on average a reduction of 21.33% in overall bitstream size over P13. Considering only scenes with reflecting mesh data, the proposed encoding method provides on average a reduction of 28.91% in overall bitstream size over P13.

In the following, information on Addition/Replacement is considered.

The encoding method presented in this Core Experiment is meant as a replacement for major parts of payloadEarlyReflections( ) The corresponding payload handler in the reference software for packets of type PLD_EARLY_REFLECTIONS is meant to be replaced accordingly.

In the following, further technical information is provided.

In particular, it is proposed to remove of Unused Variables

The RM0 bitstream parser generates the data structures earlySurfaceData and earlySurfaceConnectedData from the bitstream variables earlySurfaceDataJSON and earlySurfaceConnectedDataJSON. This data defines the reflection planes of static scene geometries and triangles which belong to connected surface areas. The motivation for splitting the set of all triangles that belong to a reflection plane into several groups of connected areas was to allow the renderer to only check a sub set during the visibility test. However, the reference software implementation no longer utilizes this distinctive information. Internally, the Intel Embree library is used for fast ray tracing with its own acceleration method (bounding volume hierarchy data structures).

It is therefore proposed to simplify these data structures by combining them into a single data structure without the connected surface information:

TABLE
earlySurfaceData( ) data structure

| Array variables | Variable Type |
|---|---|
| earlySurfaceData( ) | |
| { | |
| earlySurfaceData_surfaceIdx[s]; | int |
| earlySurfaceData_faceIdx[s][f]; | int |
| earlySurfaceData_N0[s]; | [float, float, float] |
| earlySurfaceData_d[s]; | float |
| } | |

In the following, quantization is considered.

Instead of transmitting Cartesian coordinates for the unit normal vectors N₀, it is more efficient to transmit spherical coordinates as one of the values, the distance, is a constant and does not need to be transmitted:

$${φ}_{a z i} = a tan 2 ( - x , - z )$$

$${θ}_{e l e} = a tan 2 ( y , \sqrt{{x}^{2} + {z}^{2}} )$$

$${r}_{dist} = 1$$

It is proposed to quantize the azimuth angle φ_{azi} with 12 bits and the elevation angle θₑₗₑ with 11 bits as follows:

$${N}_{a z i} = 144 \cdot floor ( \frac{{2}^{12}}{144} )$$

$$azi\_quant = round ( {φ}_{a z i} \frac{{N}_{a z i}}{2 π} )$$

and elevation angle of the surface normal N₀ as follows:

$${N}_{e l e} = 72 \cdot floor ( \frac{{2}^{11}}{72} )$$

$$ele\_quant = round ( {θ}_{e l e} \frac{{N}_{e l e}}{π} + \frac{{N}_{e l e}}{2} )$$

This quantization scheme ensures that integer multiples of 5° as well as various dividers of 360° which are power of 2 are directly on the quantization grid. The resulting 4032 quantization steps for the azimuth angle and 2017 quantization steps for the elevation angle can be regarded as quasi-lossless due to the high resolution.

For the quantization of the surface distance d we propose a 1 mm resolution. This is the same resolution which is also used for transmitting scene geometry data.

The actual number of bits that is used to transmit these values depends on the entropy coding scheme described in the following section.

In the following, entropy coding according to particular embodiments is considered.

If the symbol distribution is not uniform, entropy encoding can be used to reduce the amount of bits needed for transmitting the data. A widely used method for entropy coding is Huffman coding which uses smaller code words for more frequent symbols and longer code words for less frequent symbols, resulting in a smaller mean word size. Lately arithmetic coding gained popularity, where the complete message text is encoded at once. For the encoding of directivity data for example, an adaptive arithmetic encoding mechanism is used. This adaptive method is especially advantageous if the symbol distribution is steadily changing over time.

In the case of the early reflection metadata, we cannot make any assumption about the temporal behavior of the symbol distribution (like certain symbols occur more frequently at the beginning of the transmission while others occur more frequently at the end of the transmission). It is more reasonable to assume that the symbol distribution is fixed and can be determined during initialization of the encoder. Furthermore, adjusting the symbol distribution at runtime and using a symbol distribution which deviates from the a priori known symbol distribution actually voids the theoretical benefit of the adaptive arithmetic coding method.

For this reason it is proposed to use a classic Huffman code for entropy coding of early reflection metadata. This requires that either a pre-defined codebook is used, that the used codebook, or that the binary decoding tree together with a list of corresponding symbols is transmitted. The latter can be efficiently generated by a recursive algorithm: it traverses the decoding tree and encodes a leaf, i.e. a valid code word, by a ‘1’ and encodes a branching by a ‘0’. If the current word is not a valid code word, i.e. the algorithm is at a branching of the decoding tree, 2 recursions are performed: one for the left side where the current word is extended by a ‘0’ and one for the right side where the current word is extended by a ‘1’. The following pseudo code illustrates the encoding algorithm for the decoding tree:

Using a predefined codebook is is actually one of three options, namely, using a pre-defined codebook, or using a codebook comprising a code word list and a symbol list, or using a decoding tree and a symbol list.

```
function traverseTreeEncode(Bitstream reference bs,
      List<int> reference symbol_list,
      List<bool> code)
{
  if (code in codebookInverse) {
    bs.append(1);
    symbol = codebookInverse[code];
    symbol_list.append(symbol);
  } else {
    bs.append(0);
    traverseTreeEncode(bs, symbol_list, code + 0);
    traverseTreeEncode(bs, symbol_list, code + 1);
  }
}
```

This algorithm also generates a list of all symbols in tree traversal order. The same mechanism can be used on the decoder side to extract the decoding tree topology as well as the valid code words:

```
function traverseTreeDecode(Bitstream reference bs,
      List<int> reference code_list,
      List<bool> code)
{
  bool isLeaf = bs.readBool( );
  if (isLeaf) {
    code_list.append(code);
  } else {
    traverseTreeDecode(bs, symbol_list, code + 0);
    traverseTreeDecode(bs, symbol_list, code + 1);
  }
}
```

Since only a single bit is spent for each code word and for each branching, this results in a very efficient encoding of the decoding tree.

In addition to the topology of the decoding tree, the symbol list needs to be transmitted in tree traversal order for a complete transmission of the codebook.

In some cases transmitting the codebook in addition to the symbols might result in a bitstream which is even larger than a simple fixed length encoding. We therefore introduce a new generic purpose method for transmitting data using codebooks. Our proposed method utilizes either variable length encoding using the encoding scheme described above or a fixed length encoding. In the latter case only the word size, i.e. the number of bits for each code word, must be transmitted instead of a complete codebook. Optionally, a common offset for the integer values of the symbols may be given in the bitstream, if the difference to the offset results in a smaller word size. The following function parses such a generic codebook and returns a data structure for the current codebook instance:

| Syntax | No. of bits | Mnemonic |
|---|---|---|
| genericCodebook( ) | | |
| { | | |
| this.flagFixedLength; | 1 | uimsbf |
| this.flagOffset | 1 | |
| if (this.flagOffset) { | | uimsbf |
| wordSizeOffset; | 6 | |
| this.offset; | wordSizeOffset | uimsbf |
| } | | uimsbf |
| else { | | |
| this.offset = 0; | | |
| } | | |
| this.wordSize; | 6 | uimsbf |
| if (this.flagFixedLength) { | | |
| numCodes = 1 << this.wordSize; | | |
| for (unsigned int n = 0; n < | | |
| numCodes; n++) { | | |
| // initialize bool array of | | |
| given length | | |
| this.codeList[n] = Bitarray(n, | | |
| this.wordSize); | | |
| this.symbolList[n] = n + | | |
| this.offset; | | |
| } | | |
| } | | |
| else { | this.wordSize | uimsbf |
| Bitarray code = [ ]; | | |
| this.codeList = | | |
| traverseTreeDecode( code ); | | |
| for (int n = 0; n < | | |
| this.codeList.size( ); n++) | | |
| rawList[n]; | | |
| this.symbolList[n] = | | |
| rawList[n] + this.offset; | | |
| } | | |
| } | | |
| return this; | | |
| } | | |

In this implementation the keyword “Bitarray” is used as an alias for a bit sequence of a certain length. Furthermore, the keyword “append( )” denotes a method which extends the length of the array by one or more elements, that are added at the end.

The recursively executed tree traversal function is defined as follows:

| Syntax | No. of bits | Mnemonic |
|---|---|---|
| traverseTreeDecode(Bitarray code) | | |
| { | | |
| Bitarray codeList[ ]; | | |
| isLeaf; | 1 | uimsbf |
| if (isLeaf) { | | |
| codeList.append(code); | | |
| } | | |
| else { | | |
| Bitarray codeLeft = code; | | |
| Bitarray codeRight = code; | | |
| codeLeft.append(0); | | |
| codeRight.append(1); | | |
| codeList.append( traverseTreeDecode( | | |
| codeLeft ) ); | | |
| codeList.append( traverseTreeDecode( | | |
| codeRight ) ); | | |
| } | | |
| return codeList; | | |
| } | | |

As they have different symbol distributions, we propose to use individual codebooks for the following arrays:
earlySurfaceLengthFaceIdx
earlySurfaceFaceIdx
earlySurfaceAzi
earlySurfaceEle
earlySurfaceDist
earlyVoxelL (see next section)
earlyVoxelS (see next section)
earlyVoxelIndicesRemovedDiff (see next section)
earlyVoxelNumPaths (see next section)
earlyVoxelOrder (see next section)
earlyVoxelSurf (see next section)

In the following, Inter-Voxel Redundancy Reduction according to particular embodiments is described.

The early reflection voxel database earlyVoxelDatabase[l][s] stores a list of reflection sequences which are potentially visible for a source within the voxel with index s and a listener within the voxel with index I. In many cases this list of reflection sequences will be very similar for neighbor voxels. By reducing this inter-voxel redundancy, the bitstream size can be significantly reduced.

The proposed inter-voxel redundancy reduction uses 4 operating modes signaled by the bitstream variable earlyVoxelMode[v]. In mode 0 (“no reference”) the list of reflection sequences for source voxel earlyVoxelS[v] and listener voxel earlyVoxelL[v] is transmitted as an array with path index p and order index o using generic codebooks for the variables earlyVoxelNumPaths[v], earlyVoxelOrder[v][p], and earlyVoxelSurf[v][p][o]. In the other operating modes, the difference between a reference and the current list of reflection sequences is transmitted.

In mode 1 (“x-axis reference”) the list of reflection sequences for the current source voxel and the listener voxel neighbor in the negative x-axis direction is used as reference. A list of indices is transmitted, which specify the entries of the reference list, that need to be removed, together with a list of additional reflection sequences.

Mode 2 (“y-axis reference”) differs from mode 1 by using the listener voxel neighbor in the negative y-axis direction.

Mode 3 (“z-axis reference”) differs from mode 1 by using the listener voxel neighbor in the negative z-axis direction.

The index list earlyVoxelIndicesRemoved[v] which specifies the entries of the reference list that need to be removed can be encoded more efficiently, if a zero terminated list earlyVoxelIndicesRemovedDiff[v] of differences is transmitted instead. This reduces the entropy since smaller values become more likely and larger values become less likely, resulting in a more pronounced distribution. The conversion is performed via accumulation:

| | Variable |
|---|---|
| Variable Name | Type |
| convertVoxelIndicesRemoved( ) | |
| { | |
| for (int v = 0; v < numberOfVoxelPairs; v++) { | |
| int val = −1; | |
| numberOfIndicesRemoved = | int |
| earlyVoxelIndicesRemovedDiff[v].size( ) − 1; | |
| for (int k = 0; k < numberOfIndicesRemoved; k++) { | |
| val += earlyVoxelIndicesRemovedDiff[v][k]; | |
| earlyVoxelIndicesRemoved[v][k] = val; | int |
| } | |
| } | |
| } | |

In the following, the syntax of Generic Codebook is described.

Some payloads like payloadEarlyReflections( ) utilize individual codebooks which are defined within the bitstream using the following syntax:

TABLE
Syntax of genericCodebook( )

| Syntax | No. of bits | Mnemonic |
|---|---|---|
| genericCodebook( ) | | |
| { | | |
| this.flagFixedLength; | 1 | uimsbf |
| this.flagOffset; | 1 | uimsbf |
| if (this.flagOffset) { | | |
| wordSizeOffset; | 6 | uimsbf |
| this.offset; | wordSizeOffset | uimsbf |
| } | | |
| else { | | |
| this.offset = 0; | | |
| } | | |
| this.wordSize; | 6 | uimsbf |
| if (this.flagFixedLength) { | | |
| numCodes = 1 << this.wordSize; | | |
| for (unsigned int n = 0; n < | | |
| numCodes; n++) { | | |
| // initialize bool array of given length | | |
| this.codeList[n] = Bitarray(n, | | |
| this.wordSize); | | |
| this.symbolList[n] = n + this.offset; | | |
| } | | |
| } | | |
| else { | | |
| Bitarray code = [ ]; | | |
| this.codeList = | | |
| traverseTreeDecode( code ); | | |
| for (int n = 0; n < | | |
| this.codeList.size( ); n++) { | | |
| rawList[n]; | this.wordSize | uimsbf |
| this.symbolList[n] = rawList[n] + | | |
| this.offset; | | |
| } | | |
| } | | |
| return this; | | |
| } | | |

The code word list “codeList” is transmitted using the following recursive tree traversal algorithm where the keyword “Bitarray” is used as an alias for a bit sequence of a certain length. Furthermore, the keyword “append( )” denotes a method which extends the length of the array by one or more elements, that are added at the end:

TABLE
Syntax of traverseTreeDecode( )

| Syntax | No. of bits | Mnemonic |
|---|---|---|
| traverseTreeDecode(Bitarray code) | | |
| { | | |
| Bitarray codeList[ ]; | | |
| isLeaf; | 1 | uimsbf |
| if(isLeaf) { | | |
| codeList.append(code); | | |
| } | | |
| else { | | |
| Bitarray codeLeft = code; | | |
| Bitarray codeRight = code; | | |
| codeLeft.append(0); | | |
| codeLeft.append(1); | | |
| codeList.append( | | |
| traverseTreeDecode( codeLeft ) | | |
| ); | | |
| codeList.append( | | |
| traverseTreeDecode( codeRight | | |
| ) ); | | |
| } | | |
| return codeList; | | |
| } | | |

An instance “exampleCodebook” of such a codebook is created as follows:
exampleCodebook=genericCodebook( )

In addition to the data fields of the returned data structure, generic codebooks have a method “get_symbol( )” which reads in a valid code word from the bitstream, i.e. the n^{th} element of codeList[ ], and returns the corresponding symbol, i.e. symbolList[n]. The usage of this method is indicated as follows:
exampleVariable=exampleCodebook.get_symbol( )

In the following, a proposed syntax for early reflection payload is presented

TABLE
Syntax of payloadEarlyReflections( )

| Syntax | No. of bits | Mnemonic |
|---|---|---|
| payloadEarly Reflections( ) | | |
| { | | |
| earlyTriangleCullingDistanceOrder1; | 8 | uimsbf |
| earlyTriangleCullingDistanceOrder2; | 8 | uimsbf |
| earlyTriangleSourceDistanceOrder1; | 8 | uimsbf |
| earlyTriangleSourceDistanceOrder2; | 8 | uimsbf |
| earlyVoxelGridOriginX; | 32 | float |
| earlyVoxelGridOriginY; | 32 | float |
| earlyVoxelGridOriginZ; | 32 | float |
| earlyVoxelGridPitchX; | 32 | float |
| earlyVoxelGridPitchY; | 32 | float |
| earlyVoxelGridPitchZ; | 32 | float |
| earlyVoxelGridShapeX; | 32 | uimsbf |
| earlyVoxelGridShapeY; | 32 | uimsbf |
| earlyVoxelGridShapeZ; | 32 | uimsbf |
| earlyHasSurfaceData; | 1 | uimsbf |
| if (earlyHasSurface Data) { | | |
| earlySurfaceDataLength; | 32 | uimsbf |
| earlySurfaceData( ); | earlySurfaceDataLength * 8 | |
| } | | |
| earlyHasVoxelData; | 1 | uimsbf |
| if (earlyHasVoxelData) { | | |
| earlyVoxelDataLength; | 32 | uimsbf |
| earlyVoxelData( ); | earlyVoxelDataLength * 8 | |
| } | | |
| } | | |

TABLE
Syntax of earlySurfaceData( )

| Syntax | No. of bits | Mnemonic |
|---|---|---|
| earlySurface Data( ) | | |
| { | | |
| codebookLengthFaceIdx = | | |
| genericCodebook( ); | | |
| codebookFaceIdx = genericCodebook( ); | | |
| codebookAzi = genericCodebook( ); | | |
| codebookEle = genericCodebook( ); | | |
| codebookDist = genericCodebook( ); | | |
| earlySurfaceDistOffset; | 22 | tcimsbf |
| numberOfSurfaces; | 16 | uimsbf |
| for (int s = 0; s < numberOfSurfaces; s++) { | | |
| earlySurfaceLengthFaceIdx[s] = | | vlclbf |
| codebookLengthFaceIdx.get_symbol( ); | | |
| for (int f = 0; f < | | |
| earlySurfaceLengthFaceIdx[s]; f++) { | | |
| earlySurfaceFaceIdx[s][f] = | | vlclbf |
| codebookFaceIdx.get_symbol( ); | | |
| } | | |
| earlySurfaceAzi[s] = | | vlclbf |
| codebookAzi.get_symbol( ); | | |
| earlySurfaceEle[s] = | | vlclbf |
| codebookEle.get_symbol( ); | | |
| earlySurfaceDist[s] = | | vlclbf |
| codebookDist.get_symbol( ); | | |
| } | | |
| } | | |

TABLE
Syntax of earlyVoxelData( )

| Syntax | No. of bits | Mnemonic |
|---|---|---|
| earlyVoxelData( ) | | |
| { | | |
| codebookL = genericCodebook( ); | | |
| codebookS = genericCodebook( ); | | |
| codebookIndicesRemoved = genericCodebook( ); | | |
| codebookNumPaths = genericCodebook( ); | | |
| codebookOrder = genericCodebook( ); | | |
| codebookSurf = genericCodebook( ); | | |
| numberOfVoxelPairs; | 32 | uimsbf |
| for (int v = 0; v < numberOfVoxelPairs; v++) { | | |
| earlyVoxelL[v] = codebookL.get_symbol( ); | | vlclbf |
| earlyVoxelS[v] = codebookS.get_symbol( ); | | vlclbf |
| earlyVoxelMode[v]; | 2 | uimsbf |
| bool remove_loop = earlyVoxelMode[v] != 0; | | |
| int k = 0; | | |
| while (remove_loop) { | | |
| earlyVoxelIndicesRemovedDiff[v][k] = | | vlclbf |
| codebookIndicesRemoved.get_symbol( ); | | |
| remove_loop = | | |
| earlyVoxelIndicesRemovedDiff[v][k] != 0; | | |
| k += 1; | | |
| } | | |
| earlyVoxelNumPaths[v] = | | vlclbf |
| codebookNumPaths.get_symbol( ); | | |
| for (int p = 0; p < earlyVoxelNumPaths[v]; p++) { | | |
| earlyVoxelOrder[v][p] = | | vlclbf |
| codebookOrder.get_symbol( ); | | |
| for (int o = 0; o < earlyVoxelOrder[v][p]; o++) { | | |
| earlyVoxelSurf[v][p][0] = | | vlclbf |
| codebookSurf.get_symbol( ); | | |
| } | | |
| } | | |
| } | | |
| } | | |

In the following, a proposed data structure, namely an early reflection payload data structure is presented.

| | |
|---|---|
| earlyTriangleCullingDistanceOrder1 | Triangle culling distance |
| | for 1st order reflections. |
| earlyTriangleCullingDistanceOrder2 | Triangle culling distance |
| | for 2nd order reflections. |
| earlySourceCullingDistanceOrder1 | Source culling distance |
| | for 1st order reflections. |
| earlySourceCullingDistanceOrder2 | Source culling distance |
| | for 2nd order reflections. |
| earlyVoxelGridOriginX | x-component of the Cartesian |
| | coordinate of the voxel |
| | grid origin [0, 0, 0]. |
| earlyVoxelGridOriginY | y-component of the Cartesian |
| | coordinate of the voxel |
| | grid origin [0, 0, 0]. |
| earlyVoxelGridOriginZ | z-component of the Cartesian |
| | coordinate of the voxel |
| | grid origin [0, 0, 0]. |
| earlyVoxelGridPitchX | Voxel grid spacing along |
| | the x-axis (voxel width). |
| earlyVoxelGridPitchY | Voxel grid spacing along |
| | the y-axis (voxel length). |
| earlyVoxelGridPitchZ | Voxel grid spacing along |
| | the z-axis (voxel height). |
| earlyVoxelGridShapeX | Number of voxels along the x-axis. |
| earlyVoxelGridShapeY | Number of voxels along the y-axis. |
| earlyVoxelGridShapeZ | Number of voxels along the z-axis. |
| earlyHasSurfaceData | Flag indicating the presence |
| | of earlySurfaceData. |
| earlySurfaceDataLength | Length of the earlySurfaceData |
| | block in bytes. |
| earlyHasVoxelData | Flag indicating the presence |
| | of earlyVoxelData. |
| earlyVoxelDataLength | Length of the earlySurfaceData |
| | block in bytes. |
| earlySurfaceDistOffset | Offset in mm for earlySurfaceDist. |
| numberOfSurfaces | Number of surfaces. |
| earlySurfaceLengthFaceIdx | Array length of |
| | earlySurfaceFaceIdx. |
| earlySurfaceFaceIdx | List of triangle IDs. |
| earlySurfaceAzi | Array with azimuth angles |
| | specifying the surface |
| | normals in spherical |
| | coordinates (Hesse normal |
| | form). |
| earlySurfaceEle | Array with elevation angles |
| | specifying the surface |
| | normals in spherical |
| | coordinates (Hesse normal |
| | form). |
| earlySurfaceDist | Array with distance values |
| | (Hesse normal form). |
| numberOfVoxelPairs | Number of source & |
| | listener voxel pairs with |
| | available voxel data. |
| earlyVoxelL | Array with listener voxel indices. |
| earlyVoxelS | Array with source voxel indices. |
| earlyVoxelMode | Array specifying the encoding |
| | mode of the voxel data. |
| earlyVoxelIndicesRemovedDiff | Differentially encoded |
| | removal list specifying the |
| | indices of the reference |
| | reflection sequence list that |
| | shall be removed. |
| earlyVoxelNumPaths | Number of reflection paths. |
| earlyVoxelOrder | 2D Array specifying the |
| | reflection order. |
| earlyVoxelSurf | Reflection sequences |
| | given as 3D array of surface |
| | indices. |

In the following, renderer stages considering early reflections are proposed and and terms and definitions are provided.

### Voxel Grid:

The renderer uses voxel data to speed up the computational complex visibility check of reflected sound propagation paths. The scene is rasterized into a regular grid with a grid spacing that can be defined individually for each dimension. Each voxel is identified by a unique voxel ID and a sparse database is used to store pre-computed data for a given source/listener voxel pair. The relevant variables and data structures are:
earlyVoxelGridOriginX
earlyVoxelGridOriginY
earlyVoxelGridOriginZ
earlyVoxelGridPitchX
earlyVoxelGridPitchY
earlyVoxelGridPitchZ
earlyVoxelGridShapeX
earlyVoxelGridShapeY
earlyVoxelGridShapeZ

These variables are the basis for voxel coordinates V=[vₓ, v_{y}, v_{z}]^{T} with 3 integer numbers as components. For any point P=[pₓ, p_{y}, p_{z}] T located in the scene, the corresponding voxel coordinate is computed by the following rounding operations to the nearest integer number:

$${v}_{x} = round ( ( {p}_{x} - earlyVoxelGridOriginX ) / earlyVoxelGridPitchX ) \qquad ( 1 )$$

$${v}_{y} = round ( ( {p}_{y} - earlyVoxelGridOriginY ) / earlyVoxelGridPitchY ) \qquad ( 2 )$$

$${v}_{z} = round ( ( {p}_{z} - earlyVoxelGridOriginZ ) / earlyVoxelGridPitchZ ) \qquad ( 3 )$$

A voxel coordinate can be converted into a voxel index:

$$n = {v}_{x} + earlyVoxelGridShapeX * ( {v}_{y} + earlyVoxelGridShapeY * {v}_{z} ) \qquad ( 4 )$$

This representation is for example used in the sparse voxel database earlyVoxelDatabase[l][s][p] for the listener voxel ID/and the source voxel ID s.

### Culling Distances:

The encoder can use source and/or triangle distance culling to speed up the pre-computation of voxel data. The culling distances are encoded in the bitstream to allow the renderer to smoothly fade-out reflections that reach the used culling thresholds. The relevant variables and data structures are:
earlyTriangleCullingDistanceOrder1
earlyTriangleCullingDistanceOrder2
earlySourceCullingDistanceOrder1
earlySourceCullingDistanceOrder2

### Surface Data:

Surface data is geometrical data which defines the reflection planes on which sound is reflected. The relevant variables and data structures are:
earlySurfaceIdx[s];
earlySurfaceFaceIdx[s][f];
earlySurface_N0[s]
earlySurface_d[s]

The surface index earlySurfaceIdx[s] identifies the surface and is referenced by the sparse voxel database earlyVoxelDatabase[1][s][p]. The triangle ID list earlySurfaceFaceIdx[s][f] defines the triangles of the static mesh which belong to this surface. One of these triangles must be hit for a successful visibility test of a specular planar reflection. The reflection plane of each surface is given in Hesse normal form using the surface normal N₀ and the surface distance d which are converted as follows:

```
int max_steps_azi = 1 << 12;
int max_steps_ele = 1 << 11;
int num_steps_azi = 144 * (max_steps_azi / 144);
int num_steps_ele = 72 * (max_steps_ele / 72);
int shift_ele = num_steps_ele / 2;
float quant2azi = double(2.0 * M_PI) / double(num_steps_azi);
float quant2ele = double(M_PI) / double(num_steps_ele);
float quant2dist = 0.001f;
for (int s = 0; s < numberOfSurfaces; s++) {
  earlySurfaceIdx[s] = s;
  float azi = earlySurfaceAzi[s] * quantZazi;
  float ele = (earlySurfaceEle[s] − shift_ele) * quant2ele;
  earlySurface_N0[s][0] = −1.0 * sin(azi) * cos(ele);
  earlySurface_N0[s][1] = sin(ele);
  earlySurface_N0[s][2] = −1.0 * cos(azi) * cos(ele);
  earlySurface_d[s] = (earlySurfaceDist[s] + dist_offset) *
quant2dist;
}
```

### Voxel Data

Early Reflection Voxel Data is a sparse voxel database containing lists of reflection sequences of potentially visible image sources for given pairs of source and listener voxels. The entries of the database can either be undefined for the case that the given pair of source and listener voxel is not specified in the bitstream, they can be an empty list, or they can contain a list of surface connected IDs. The relevant variables and data structures are:
numberOfVoxelPairs
earlyVoxelL[v]
earlyVoxelS[v]
earlyVoxelMode[v]
earlyVoxelIndicesRemovedDiff[v][k]
earlyVoxelNumPaths[v]
earlyVoxelOrder[v][p]
earlyVoxelSurf[v][p][o]

The sparse voxel database earlyVoxelDatabase[l][s][p] is derived from these variables by the following algorithm:

```
int delta_x = voxelCoordinateToVoxelIndex( {1, 0, 0} );
int delta_y = voxelCoordinateToVoxelIndex( {0, 1, 0} );
int delta_z = voxelCoordinateToVoxelIndex( {0, 0, 1} );
int delta_list[4] = { 0, −delta_x, −delta_y, −delta_z };
for (int v = 0; v < numberOfVoxelPairs; v++) {
  PathList path_list;
  int l = earlyVoxelL[v];
  int s = earlyVoxelS[v];
  int mode = earlyVoxelMode[v];
  if (mode != 0) {
    int l_ref = l + delta_list[mode];
    path_list = earlyVoxelDatabase[l_ref][s];
    // generate list with removed items in reverse order
    int numberOfIndicesRemoved =
        length(earlyVoxelIndicesRemovedDiff[v]) − 1;
    int listIndicesRemoved[numberOfIndicesRemoved];
    int val = −1;
    for (int k = 0; k < numberOfIndicesRemoved; k++) {
      val += earlyVoxelIndicesRemovedDiff[v][k];
      list IndicesRemoved[numberOfIndicesRemoved − 1 − k] =
val;
    }
    // remove reflection sequences
    for (int k = 0; k < numberOfIndicesRemoved; k++) {
      path_list.erase(listIndicesRemoved[k]);
    }
  }
  // add reflection sequences
  for (int p = 0; p < earlyVoxelNumPaths[v]; p++) {
    path_list.append(earlyVoxelSurf[v][p]);
  }
  // add sorted path list to sparse voxel database
  path_list = shortlex_sort(path_list);
  int num_paths = length(path_list);
  for (int p = 0; p < num_paths; p++) {
    earlyVoxelDatabase[l][s][p] = path_list[p];
  }
}
```

In this algorithm, the function voxelCoordinateToVoxelIndex( ) denotes the voxel coordinate to voxel index conversion. The keyword PathList denotes a list of integer arrays which can be modified by the method append( ), that adds an element at the end of the list, and the method erase( ) that removes a list element at a given position. Furthermore, the function shortlex_sort( ) denotes a sorting function which sorts the given list of reflection sequences in shortlex order.

### Complexity Evaluation

The decoder is simplified since a parsing step of the JSON data is no longer needed while the runtime complexity of the renderer is not affected by the proposed changes.

### Evidence for the Merit

In order to verify that the proposed method works correctly and to prove its technical merit, we encoded all “test 1” and “test 2” scenes and compared the size of the early reflection metadata with the encoding result of the P13 encoder.

### Data Compression

Table lists the size of payloadEarlyReflections for the P13 encoder (“old size/bytes”) and a variant of the P13 encoder with the proposed encoding method (“new size/bytes”). The last column lists the achieved compression ratio, i.e. the ratio of the old and the new payload size.

In all cases the proposed method results in smaller payload sizes. For all scenes with reflecting scene objects, i.e. scenes with mesh data, a compression ratio greater than 10 was achieved. For some scenes (“SingerInTheLab” and “VirtualBasketball”) a compression ratio close to or even greater than 100 was achieved.

TABLE
size comparison of payloadEarlyReflections

| | old size/ | new size/ | compression |
|---|---|---|---|
| Scene | bytes | bytes | ratio |
| ARBmw | 49 | 41 | 1.20 |
| ARHomeConcert_Test1 | 49 | 41 | 1.20 |
| ARPortal | 3635 | 208 | 17.48 |
| Battle | 71474 | 3794 | 18.84 |
| Beach | 49 | 41 | 1.20 |
| Canyon | 442297 | 20591 | 21.48 |
| Cathedral | 4476209 | 122576 | 36.52 |
| DowntownDrummer | 170140 | 6745 | 25.22 |
| GigAdvertisement | 49 | 41 | 1.20 |
| Hospital | 85350 | 4673 | 18.26 |
| OutsideHOA | 44289 | 3185 | 13.91 |
| Park | 4002785 | 162528 | 24.63 |
| ParkingLot | 948184 | 53121 | 17.85 |
| Recreation | 6690228 | 372541 | 17.96 |
| SimpleMaze | 15866 | 975 | 16.27 |
| SingerInTheLab | 85016 | 714 | 119.07 |
| SingerInYourLab_small | 49 | 41 | 1.20 |
| VirtualBasketball | 478238 | 4853 | 98.54 |
| VirtualPartition | 301 | 65 | 4.63 |

In the following, the total bitstream saving is considered.

The following table lists the saving of total bitstream size in percent. On average, the total bitstream size was reduced by 21.33%. Considering only scenes with mesh data, the total bitstream sizes were reduced by 28.91% on average.

TABLE
saving of total bitstream size

| | old total | new total | saving/ |
|---|---|---|---|
| Scene | size/bytes | size/bytes | % |
| ARBmw | 7827 | 7819 | 0.10 |
| ARHomeConcert_Test1 | 5963 | 5955 | 0.13 |
| ARPortal | 40745 | 37318 | 8.41 |
| Battle | 285137 | 217457 | 23.74 |
| Beach | 6248 | 6240 | 0.13 |
| Canyon | 1421293 | 999587 | 29.67 |
| Cathedral | 11110385 | 6756752 | 39.19 |
| DowntownDrummer | 440299 | 276904 | 37.11 |
| GigAdvertisement | 6553 | 6545 | 0.12 |
| Hospital | 3649408 | 3568731 | 2.21 |
| OutsideHOA | 118206 | 77102 | 34.77 |
| Park | 19027460 | 15187203 | 20.18 |
| ParkingLot | 1973557 | 1078494 | 45.35 |
| Recreation | 30335390 | 24017703 | 20.83 |
| SimpleMaze | 840490 | 825599 | 1.77 |
| SingerInTheLab | 99631 | 15329 | 84.61 |
| SingerInYourLab_small | 9726 | 9718 | 0.08 |
| VirtualBasketball | 871379 | 397994 | 54.33 |
| VirtualPartition | 9295 | 9059 | 2.54 |

### Data Validation and Quantization Errors

The following table lists the result of our data validation test for an extended test set, which additionally includes all “test 4” scenes plus further scenes that did not make it into the official test repository, where we compared the decoded metadata, e.g., earlySurfaceData and earlyVoxelData, with the output of the P13 decoder. For the P13 payload, the connected surface data and the surface data was combined in order to be able to compare it to the new encoding method. The validation result “identical structure” means that both payloads had the same reflecting surfaces and that the data only differed by the expected quantization errors.

For all scenes the decoded earlyVoxelData was identical and the decoded earlySurfaceData was either identical or structurally identical.

TABLE
validation of transmitted data

| Scene | earlySurfaceData | earlyVoxelData |
|---|---|---|
| ARBmw | identical | identical |
| ARHomeConcert_Test1 | identical | identical |
| ARPortal | identical structure | identical |
| BOrchestra | identical | identical |
| Battle | identical structure | identical |
| Beach | identical | identical |
| Canyon | identical structure | identical |
| Cathedral | identical structure | identical |
| DowntownDrummer | identical structure | identical |
| FountainMusicVR | identical structure | identical |
| GigAdvertisement | identical | identical |
| Hospital | identical structure | identical |
| LivingRoom | identical structure | identical |
| MultiZoneMusic | identical | identical |
| MultiZoneMusic_objects | identical structure | identical |
| Offices | identical structure | identical |
| Outside | identical structure | identical |
| OutsideHOA | identical structure | identical |
| Park | identical structure | identical |
| ParkingLot | identical structure | identical |
| Recreation | identical structure | identical |
| Restaurant | identical | identical |
| SimpleMaze | identical structure | identical |
| SingerInTheLab | identical structure | identical |
| SingerInYourLab | identical | identical |
| SingerInYourLab_small | identical | identical |
| VirtualBasketball | identical structure | identical |
| VirtualPartition | identical structure | identical |

The following table ists the minimum, mean, median, and maximum quantization error in mm of the transmitted plane normal N₀ after conversion into Cartesian coordinates. The maximum quantization error of 1.095 mm corresponds to an angular deviation of 0.063°. With a resolution of 0.088° per quantization step and hence 0.044° maximum quantization error per axis, the observed results are in good accordance with the theoretical values.

A maximum angular deviation of 0.063° for the surface normal vector N₀ is so small that the transmission can be regarded as quasi lossless.

TABLE
quantization error of the normal unit vector of the surfaces in mm

| Scene | min | mean | median | max |
|---|---|---|---|---|
| ARPortal | 0 | 0.164 | 6.56e−5 | 0.728 |
| Battle | 0 | 0.254 | 0.100 | 1.035 |
| Canyon | 4.37e−5 | 0.521 | 0.529 | 1.066 |
| Cathedral | 1.19e−5 | 0.358 | 0.349 | 0.985 |
| DowntownDrummer | 0 | 0.284 | 0.239 | 0.917 |
| FountainMusicVR | 0 | 0.063 | 4.37e−5 | 0.729 |
| Hospital | 0 | 0.304 | 0.266 | 1.003 |
| LivingRoom | 0 | 0.036 | 4.37e−5 | 0.650 |
| MultiZoneMusic_ | 0 | 0.186 | 8.51e−3 | 0.696 |
| objects | | | | |
| Offices | 1.19e−5 | 0.259 | 0.349 | 0.803 |
| Outside | 0 | 3.84e−5 | 4.37e−5 | 8.74e−5 |
| OutsideHOA | 0 | 0.063 | 4.37e−5 | 0.729 |
| Park | 0 | 0.392 | 0.430 | 0.828 |
| ParkingLot | 1.19e−5 | 0.569 | 0.603 | 1.095 |
| Recreation | 0 | 0.515 | 0.533 | 1.087 |
| SimpleMaze | 0 | 3.97e−5 | 4.37e−5 | 8.74e−5 |
| SingerInTheLab | 1.19e−5 | 0.249 | 0.349 | 0.349 |
| Testroom | 0 | 3.69e−5 | 4.37e−5 | 8.74e−5 |
| VirtualBasketball | 1.19e−5 | 0.399 | 0.349 | 0.932 |
| VirtualPartition | 0 | 4.37e−5 | 4.37e−5 | 8.74e−5 |

The following table lists the minimum, mean, median, and maximum quantization error in mm of the transmitted plane distance. With a resolution of 1 mm per quantization step, the observed maximum deviation of 0.519 mm is in good accordance with the expected maximum value of 0.5 mm. The overshoot can be explained by the limited precision of the used single precision floating point variables which do not provide sufficient sub-millimeter resolution for large scenes like “Park”, “ParkingLot”, and “Recreation”.

A maximum deviation of 0.519 mm for the surface distance d is so small that the transmission can be regarded as quasi lossless.

TABLE
quantization error of the surface distances in mm

| Scene | min | mean | median | max |
|---|---|---|---|---|
| ARPortal | 0 | 0.259 | 0.277 | 0.500 |
| Battle | 0 | 0.141 | 0.047 | 0.495 |
| Canyon | 0 | 0.254 | 0.250 | 0.502 |
| Cathedral | 0 | 0.249 | 0.244 | 0.504 |
| DowntownDrummer | 0 | 0.223 | 0.201 | 0.504 |
| FountainMusicVR | 2.38e−4 | 0.180 | 0.101 | 0.423 |
| Hospital | 0 | 0.158 | 0.087 | 0.498 |
| LivingRoom | 0 | 0.204 | 0.200 | 0.500 |
| MultiZoneMusic_ | 0 | 0.193 | 0.103 | 0.475 |
| objects | | | | |
| Offices | 1.91e−3 | 0.254 | 0.236 | 0.500 |
| Outside | 0 | 0.133 | 0.099 | 0.299 |
| OutsideHOA | 2.38e−4 | 0.180 | 0.101 | 0.423 |
| Park | 0 | 0.251 | 0.244 | 0.519 |
| ParkingLot | 0 | 0.247 | 0.244 | 0.519 |
| Recreation | 0 | 0.248 | 0.244 | 0.519 |
| SimpleMaze | 0 | 2.98e−5 | 0 | 2.38e−4 |
| SingerInTheLab | 0 | 0.050 | 0.050 | 0.101 |
| Testroom | 0 | 1.12e−4 | 0 | 4.77e−4 |
| VirtualBasketball | 9.54e−4 | 0.241 | 0.248 | 0.500 |
| VirtualPartition | 0 | 0 | 0 | 0 |

In an embodiment, a binary encoding method for earlySurfaceData( ) and earlyVoxelData( ) as part of the early reflection metadata in payloadEarlyReflections( ) is provided. For the test set comprising 30 AR and VR scenes, we compared the decoded data with the data decoded by the P13 decoder and observed only expected quantization errors. The quantization errors of the surface data was so small that the transmission can be regarded as quasi-lossless. The transmitted voxel data was identical.

In all cases the proposed method results in smaller payload sizes. For all scenes with reflecting scene objects, i.e. scenes with mesh data, a compression ratio greater than 10 was achieved. For some scenes (“SingerInTheLab” and “VirtualBasketball”), a compression ratio close to or even greater than 100 was achieved. For all “test 1” and “test 2” scenes, the proposed encoding method provides on average a reduction of 21.33% in overall bitstream size over P13. Considering only scenes with reflecting mesh data, the proposed encoding method provides on average a reduction of 28.91% in overall bitstream size over P13.

The proposed encoding method does not affect the runtime complexity of the renderer.

Moreover, the proposed replacement also reduces the library dependencies of the reference software since generating and parsing JSON documents is no longer needed.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software or at least partially in hardware or at least partially in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitory.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are preferably performed by any hardware apparatus.

The apparatus described herein may be implemented using a hardware apparatus, or using a computer, or using a combination of a hardware apparatus and a computer.

The methods described herein may be performed using a hardware apparatus, or using a computer, or using a combination of a hardware apparatus and a computer.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. An apparatus for generating one or more audio output signals from one or more encoded audio signals, wherein the apparatus comprises:
at least one entropy decoding module for decoding encoded additional audio information, when the encoded additional audio information is entropy-encoded, to acquire decoded additional audio information, and
a signal processor for generating the one or more audio output signals depending on the one or more encoded audio signals and depending on the decoded additional audio information.

2. An apparatus according to claim 1,
wherein the apparatus further comprises:
at least one non-entropy decoding module for decoding the encoded additional audio information, when the encoded additional audio information is not entropy-encoded, to acquire the decoded additional audio information, and
a selector for selecting one of the at least one entropy decoding module and of the at least one non-entropy decoding module for decoding the encoded additional audio information depending on whether or not the encoded additional audio information is entropy-encoded.

3. An apparatus according to claim 1,
wherein the encoded additional audio information comprises augmented reality data or virtual reality data.

4. An apparatus according to claim 1,
wherein the encoded additional audio information depends on a real listening environment or depends on a virtual listening environment or depends on an augmented listening environment.

5. An apparatus according to claim 4,
information depending on one or more propagations of one or more sound waves along one or more propagation paths in the real listening environment or in the virtual listening environment or in the augmented listening environment.

6. An apparatus according to claim 5,
wherein the propagation information is reflection information depending on one or more reflections at one or more reflection objects of one or more sound waves propagating along one or more propagation paths in the real listening environment or in the virtual listening environment or in the augmented listening environment; or
wherein the propagation information is diffraction information depending on one or more diffractions at one or more diffraction objects of one or more sound waves propagating along one or more propagation paths in the real listening environment or in the virtual listening environment or in the augmented listening environment.

7. An apparatus according to claim 1,
wherein the encoded additional audio information comprises data for rendering early reflections, wherein the signal processor is configured to generate the one or more audio output signals depending on the data for rendering early reflections.

8. An apparatus according to claim 1,
wherein the signal processor is configured to generate a binaural signal comprising two binaural channels as the one or more audio output signals; or
wherein the at least one entropy decoding module comprises a Huffman decoding module for decoding the encoded additional audio information, when the encoded additional audio information is Huffman-encoded; or
wherein the at least one entropy decoding module comprises an arithmetic decoding module for decoding the encoded additional audio information, when the encoded additional audio information is arithmetically-encoded.

9. An apparatus according to claim 2,
wherein the selector is configured to select one of the at least one non-entropy decoding module and of the Huffman decoding module and of the arithmetic decoding module for decoding the encoded additional audio information; or
wherein the at least one non-entropy decoding module comprises a fixed-length decoding module for decoding the encoded additional audio information, when the encoded additional audio information is fixed-length-encoded; or
wherein the apparatus is configured to receive selection information, and wherein the selector is configured to select one of the at least one entropy decoding module and of the at least one non-entropy decoding module depending on the selection information.

10. An apparatus according to claim 1,
wherein the apparatus is configured to receive a codebook or a coding tree on which the encoded additional audio information depends, and,
wherein the at least entropy decoding module is configured to decode the encoded additional audio information using the codebook or using the coding tree.

11. An apparatus according to claim 10,
wherein the apparatus is configured to receive an encoding of a structure of the coding tree on which the encoded additional audio information depends,
wherein the at least entropy decoding module is configured to reconstruct a plurality of codewords of the coding tree depending on the structure of the coding tree, and
wherein the at least entropy decoding module is configured to decode the encoded additional audio information using the codewords of the coding tree.

12. An apparatus according to claim 1,
wherein the apparatus further comprises a memory having stored thereon a codebook or a coding tree, wherein the at least entropy decoding module is configured to decode the encoded additional audio information using the codebook or using the coding tree; or
wherein the apparatus is configured to receive the encoded additional audio information comprising a plurality of transmitted symbols and an offset value, and wherein the at least one non-entropy decoding module is configured to decode the encoded additional audio information using the plurality of transmitted symbols and using the offset value.

13. An apparatus according to claim 7,
wherein the data for rendering early reflections comprises information on a location of one or more walls, being one or more real walls or virtual walls in an environment,
wherein the signal processor is configured to generate the one or more audio output signals depending on the information on the location of one or more walls.

14. An apparatus according to claim 13,
wherein the information on each wall of the one or more walls comprises information on a azimuth angle and/or an elevation angle of said wall, wherein the azimuth angle of said wall is entropy-encoded and/or the elevation angle of said wall is entropy-encoded, and
wherein one or more entropy decoding modules of the at least one entropy decoding module are configured to decode an entropy-encoded azimuth angle of said wall and/or an entropy-encoded elevation angle of said wall.

15. An apparatus according to claim 10,
wherein the information on each wall of the one or more walls comprises information on a azimuth angle and/or an elevation angle of said wall, wherein the azimuth angle of said wall is entropy-encoded and/or the elevation angle of said wall is entropy-encoded,
wherein one or more entropy decoding modules of the at least one entropy decoding module are configured to decode an entropy-encoded azimuth angle of said wall and/or an entropy-encoded elevation angle of said wall, and
wherein said one or more of the at least one entropy decoding module are configured to decode the entropy-encoded azimuth angle of said wall and/or the entropy-encoded elevation angle of said wall using the codebook or the coding tree.

16. An apparatus according to claim 1,
wherein the encoded additional audio information comprises voxel position information, wherein the position information comprises information on one or more positions of one or more voxels out of a plurality of voxels within a three-dimensional coordinate system, wherein the signal processor is configured to generate the one or more audio output signals depending on the voxel position information; or
wherein the at least one entropy decoding module is configured to decode encoded additional audio information being entropy-encoded, wherein the encoded additional audio information being entropy-encoded comprises at least one of the following:
a list of triangle indexes,
an array length of a list of triangle indexes,
an array with azimuth angles specifying surface normals in spherical coordinates,
an array with elevation angles specifying surface normals in spherical coordinates,
an array with distance values,
an array with positions of a listener,
an array with positions of one or more sound sources,
a removal list or a removal set, specifying indices of reflection sequences of a set of reflection sequences that shall be removed or a reference reflection sequence list that shall be removed,
a number of reflection sequences or a number of reflection paths,
an array specifying a reflection order,
reflection sequences.

17. An apparatus for encoding one or more audio signals and additional audio information, wherein the apparatus comprises:
an audio signal encoder for encoding the one or more audio signals to acquire one or more encoded audio signals, and
at least one entropy encoding module for encoding the additional audio information using entropy encoding to acquire encoded additional audio information.

18. An apparatus according to claim 17,
wherein the apparatus further comprises:
at least one non-entropy encoding module for encoding the additional audio information to acquire the encoded additional audio information, and
a selector for selecting one of the at least one entropy encoding module and of the at least one non-entropy encoding module for encoding the additional audio information depending on a symbol distribution within the additional audio information that is to be encoded.

19. An apparatus according to claim 17,
wherein the encoded additional audio information comprises augmented reality data or virtual reality data.

20. An apparatus according to claim 17,
wherein the encoded additional audio information depends on a real listening environment or depends on a virtual listening environment or depends on an augmented listening environment.

21. An apparatus according to claim 20,
information depending on one or more propagations of one or more sound waves along one or more propagation paths in the real listening environment or in the virtual listening environment or in the augmented listening environment.

22. An apparatus according to claim 21,
wherein the propagation information is reflection information depending on one or more reflections at one or more reflection objects of one or more sound waves propagating along one or more propagation paths in the real listening environment or in the virtual listening environment or in the augmented listening environment; or
wherein the propagation information is diffraction information depending on one or more diffractions at one or more diffraction objects of one or more sound waves propagating along one or more propagation paths in the real listening environment or in the virtual listening environment or in the augmented listening environment.

23. An apparatus according to claim 17,
wherein the encoded additional audio information comprises data for rendering early reflections.

24. An apparatus according to claim 17,
wherein the at least one entropy encoding module comprises a Huffman encoding module for encoding the additional audio information using Huffman encoding; or
wherein the at least one entropy encoding module comprises an arithmetic encoding module for encoding the additional audio information using arithmetic encoding.

25. An apparatus according to claim 18,
wherein the selector is configured to select one of the at least one non-entropy encoding module and of the Huffman encoding module and of the arithmetic encoding module for encoding the additional audio information; or
wherein the at least one non-entropy encoding module comprises a fixed-length encoding module for encoding the additional audio information; or
wherein the apparatus is configured to generate selection information indicating one of the at least one entropy encoding module and of the at least one non-entropy encoding module which has been employed for encoding the additional audio information.

26. An apparatus according to claim 17,
wherein the apparatus is configured to transmit a codebook or a coding tree which has been employed to encode the additional audio information.

27. An apparatus according to claim 26,
wherein the apparatus is configured to transmit an encoding of a structure of the coding tree on which the encoded additional audio information depends.

28. An apparatus according to claim 17,
wherein the apparatus further comprises a memory having stored thereon a codebook or a coding tree,
wherein the at least entropy encoding module is configured to encode the additional audio information using the codebook or using the coding tree; or
wherein the at least one entropy encoding module is configured to encode the additional audio information such that the encoded additional audio information comprises a plurality of transmitted symbols and an offset value.

29. An apparatus according to claim 23,
wherein the data for rendering early reflections comprises information on a location of one or more walls, being one or more real walls or virtual walls in an environment.

30. An apparatus according to claim 29,
wherein the information on each wall of the one or more walls comprises information on a azimuth angle and/or an elevation angle of said wall, wherein the azimuth angle of said wall is entropy-encoded and/or the elevation angle of said wall is entropy-encoded, and
wherein one or more entropy encoding modules of the at least one entropy encoding module are configured to encode the additional audio information such that the encoded additional audio information comprises an entropy-encoded azimuth angle of said wall and/or an entropy-encoded elevation angle of said wall.

31. An apparatus according to claim 26,
wherein the information on each wall of the one or more walls comprises information on a azimuth angle and/or an elevation angle of said wall, wherein the azimuth angle of said wall is entropy-encoded and/or the elevation angle of said wall is entropy-encoded,
wherein one or more entropy encoding modules of the at least one entropy encoding module are configured to encode the additional audio information such that the encoded additional audio information comprises an entropy-encoded azimuth angle of said wall and/or an entropy-encoded elevation angle of said wall, and
wherein said one or more entropy encoding modules are configured to encode the entropy-encoded azimuth angle of said wall and/or the entropy-encoded elevation angle of said wall using the codebook or the coding tree.

32. An apparatus according to claim 17,
wherein the encoded additional audio information comprises voxel position information, wherein the position information comprises information on one or more positions of one or more voxels out of a plurality of voxels within a three-dimensional coordinate system; or
wherein the at least one entropy encoding module is configured to encode the additional audio information using entropy encoding, wherein the encoded additional audio information comprises at least one of the following:
a list of triangle indexes,
an array length of a list of triangle indexes,
an array with azimuth angles specifying surface normals in spherical coordinates,
an array with elevation angles specifying surface normals in spherical coordinates,
an array with distance values,
an array with positions of a listener,
an array with positions of one or more sound sources,
a removal list or a removal set, specifying indices of reflection sequences of a set of reflection sequences that shall be removed or a reference reflection sequence list that shall be removed,
a number of reflection sequences or a number of reflection paths,
an array specifying a reflection order,
reflection sequences.

33. A system comprising:
an apparatus according to claim 17 for encoding one or more audio signals and additional audio information to acquire one or more encoded audio signals and encoded additional audio information, and
an apparatus for generating one or more audio output signals from one or more encoded audio signals, wherein the apparatus comprises:
at least one entropy decoding module for decoding encoded additional audio information, when the encoded additional audio information is entropy-encoded, to acquire decoded additional audio information, and
a signal processor for generating the one or more audio output signals depending on the one or more encoded audio signals and depending on the decoded additional audio information.

34. A method for generating one or more audio output signals from one or more encoded audio signals, wherein the method comprises:
decoding encoded additional audio information, when the encoded additional audio information is entropy-encoded, to acquire decoded additional audio information, and
generating the one or more audio output signals depending on the one or more encoded audio signals and depending on the decoded additional audio information.

35. A method for encoding one or more audio signals and additional audio information, wherein the method comprises:
encoding the one or more audio signals to one or more encoded audio signals, and
encoding the additional audio information using entropy encoding to acquire encoded additional audio information.

36. A non-transitory digital storage medium having a computer program stored thereon to perform the method according to claim 34 for generating one or more audio output signals from one or more encoded audio signals, when said computer program is run by a computer.

37. A non-transitory digital storage medium having a computer program stored thereon to perform the method according to claim 35 for encoding one or more audio signals and additional audio information, when said computer program is run by a computer.
